(19) United States
(12) Patent Application Publication
(10) Pub. No.: US 2015/0311470 A1
(43) Pub. Date: Oct. 29, 2015

(54) CONDUCTIVE SUPPORT FOR AN OLED DEVICE, AND OLED DEVICE INCORPORATING THE SAME

(71) Applicant: SAINT-GOBAIN GLASS FRANCE, Courbevoie (FR)

(72) Inventors: Denis GUIMARD, Paris (FR); Anne LELARGE, Paris (FR)

(21) Appl. No.: 14/651,795

(22) PCT Filed: Dec. 10, 2013
(86) PCT No.: PCT/FR2013/053008

§ 371 Date: Jun. 12, 2015

(30) Foreign Application Priority Data
Dec. 13, 2012 (FR) 1262009

(51) Int. Cl. H01L 51/52; H01L 51/56

(52) U.S. Cl. CPC H01L 51/5215; H01L 51/56; H01L 2251/306; H01L 2251/308; H01L 2251/558; H01L 2251/562

(57) ABSTRACT

A conductive support for an OLED, includes a dielectric sublayer, with an optical thickness L1 of greater than 20 nm and less than 180 nm, including a first crystalline contact layer based on zinc oxide, a first silver layer of less than 20 nm, a dielectric separating layer, with an optical thickness L2 of greater than 80 nm and less than 280 nm, including in this order a layer of zinc oxide with a thickness e₂, directly on the first silver layer, an optional amorphous layer, based on tin zinc or indium zinc or indium zinc tin oxide with a thickness eᵢ of less than 15 nm, a second layer of zinc oxide, with a thickness e_{c2}, the sum of e_{c2}+e₂ being at least 30 nm, a second silver layer of less than 20 nm, a metal overblocker of less than 3 nm, a dielectric electrically conductive overlayer.

The present invention relates to a conductive support for an organic light-emitting diode device and also to an organic light-emitting diode device incorporating it.

The known organic light-emitting diode systems or OLEDs comprise one or more organic light-emitting materials fed with electricity via electrodes generally in the form of two electrically conductive layers surrounding these materials.

These electrically conductive layers commonly comprise a layer based on indium oxide, generally tin-doped indium oxide more commonly known under the abbreviation ITO. ITO layers have been particularly studied. They may be readily deposited by magnetic field-assisted cathodic sputtering, either using an oxide target (unreactive sputtering) or using a target based on indium and tin (reactive sputtering in the presence of an oxidizing agent such as oxygen) and their thickness is of the order of 100 to 150 nm. However, this ITO layer has a certain number of drawbacks. Firstly, the material and the high-temperature (350° C.) deposition process for improving the conductivity give rise to additional costs. The resistance per square remains relatively high (about 10Ω per square) unless the thickness of the layers is increased beyond 150 nm, which results in a decrease in transparency and an increase in surface roughness, which is critical for OLEDs.

In addition, for uniform lighting on large surfaces, it is necessary to form a discontinuous lower electrode, typically by forming zones of electrodes of a few mm² and to drastically reduce the distance between each zone of electrodes, typically of the order of about ten microns. To do this use is made especially of expensive and complex photolithography and passivation techniques.

Thus, novel electrode structures develop using a thin metal layer instead of ITO in order to manufacture OLED devices emitting a substantially white light for lighting.

The use of stacks of thin layers comprising one or more layers of silver to increase the conductivity of anodes based on TCO is also known.

An OLED anode comprising both an ITO layer and two layers of silver is described in International patent application WO 2009/083 693 in the name of the Applicant. In the examples, the anode in the form of a two-layer silver stack comprises, in this order:
an antireflection sublayer of given optical thickness L1 composed of an optional Si₃N₄ base layer, a first amorphous “smoothing” layer made of tin zinc oxide (SnZnO), a first crystalline contact layer of aluminum-doped zinc oxide (AZO),
a first layer of silver,
a layer of Ti forming a first overblocker,
a separating layer of given optical thickness L2 composed of an additional layer of AZO, a second amorphous smoothing layer of SnZnO, a second contact layer of AZO,
a second layer of silver,
a layer of Ti forming a second overblocker,
an overlayer of ITO.

The first smoothing layer of tin zinc mixed oxide (SnZnO) makes it possible to limit the roughness of the following layers.

To minimize the roughness of the anode, the first contact layer of AZO, the additional layer of AZO and the second contact layer of AZO are thin (5 nm) on account of their crystallinity, whereas the intermediate amorphous layer is thick.

Moreover, each overblocker forms a “sacrificial” protective layer which prevents impairment of the silver in one and/or other of the following configurations:
if the layer which is mounted on the silver layer (either the first or the second) is deposited using a reactive plasma (oxygen, nitrogen, etc.), for example if the layer of oxide mounted thereon is deposited by cathodic sputtering,
when the electrode coat undergoes, subsequent to deposition, a heat treatment or even a chemical treatment.

The optical thicknesses L1 and L2 and the geometrical thicknesses of the silver layers are also adjusted to significantly reduce the colorimetric variation as a function of the observation angle.

Table A below details the nature, the geometrical thickness e and the optical thicknesses L1 and L2 of the various layers of these examples, and also the main optical and electrical characteristics of the stacks.

TABLE A

| | Examples of WO 2009/083 693 | | | | |
|---|---|---|---|---|---|
| | No. 1 | No. 2 | No. 3 | No. 4 | No. 5 |
| Layers/e (nm) (starting | | | | | |
| from the glass) | | | | | |
| Si₃N₄:Al | 30 | 23 | 26 | 15 | |
| SnZnO:Sb | 5 | 7 | 4 | 6 | 45 |
| AZO | 5 | 3 | 6 | 4 | 5 |
| Ag | 8 | 9 | 11 | 9 | 8 |
| Ti | 0.5 | <1 | <1 | <1 | <1 |
| AZO | 5 | 5 | 5 | 5 | 5 |
| SnZnO:Sb | 60 | 46 | 49 | 39 | 75 |
| AZO | 5 | 5 | 5 | 5 | 5 |
| Ag | 8 | 8 | 8 | 8 | 8 |
| Ti | 0.5 | <1 | <1 | <1 | <1 |
| ITO | 20 | 22 | 18 | 32 | 50 |
| Properties of the stack | | | | | |
| L1 (nm) | 80 | 65 | 70 | 50 | 100 |
| L2 (nm) | 140 | 110 | 115 | 100 | 170 |
| T_{L} (%) | 80 | 80 | 77 | 75 | |
| R per square (Ω/square) | 2.7 | 2.6 | 2.4 | 2.6 | |

The deposition conditions for each of the layers are as follows:
the layers of Si₃N₄:Al are deposited by reactive sputtering using an aluminum-doped silicon target, at a pressure of 0.25 Pa under an argon/nitrogen atmosphere,
the layers of SnZnO:Sb are deposited by reactive sputtering using an antimony-doped zinc and tin target comprising by mass 65% Sn, 34% Zn and 1% Sb, at a pressure of 0.2 Pa and under an argon/oxygen atmosphere,
the layers of silver are deposited using a silver target, at a pressure of 0.8 Pa under an atmosphere of pure argon,
the layers of Ti are deposited using a titanium target, at a pressure of 0.8 Pa under an atmosphere of pure argon,
the layers of AZO are deposited by reactive sputtering using an aluminum-doped zinc target, at a pressure of 0.2 Pa and under an argon/oxygen atmosphere,
the overlayers of ITO are deposited using a ceramic target under an argon/oxygen atmosphere, at a pressure of 0.2 Pa and under an argon/oxygen atmosphere.

These electrodes do not ensure sufficient uniformity of luminance for large-sized OLEDs nor even do they maximize the light power of the OLED and their reliability is not ensured.

The set aim of the invention is that of providing an OLED device that is efficient (in terms of homogeneity of luminance, and/or of light efficiency). To do this, the invention proposes an electrode which has adequate electrical and optical performance qualities, most particularly after annealing.

The electrode must also be reliable, i.e. it must not promote short-circuits.

To this end, a first subject of the invention is a conductive support for an OLED device comprising a transparent glass substrate, preferably mineral, bearing, on a first main face, a transparent electrode, known as the lower electrode, and which comprises the following stack of thin layers in this order (starting from the substrate):
a dielectric sublayer, with an optical thickness L1 of greater than 20 nm, preferably greater than or equal to 40 nm, and less than 180 nm, comprising:
   a first crystalline contact (mono)layer, based on zinc oxide, which is preferably doped, and better still consists essentially of a zinc oxide preferably doped with aluminum and/or with gallium (AZO, (A)GZO), this first contact layer preferably having a thickness e_{c1} of less than 15 nm, better still less than or equal to 10 nm, and preferably at least 3 nm,
a first metallic (mono)layer based on silver (preferably made of silver), with a given thickness e_{ag1} of less than 20 nm, better still less than or equal to 15 nm, and preferably of at least 3 nm and even of at least 5 nm, (mono)layer preferably directly on the first crystalline contact layer,
a dielectric separating (mono or multi)layer, with an optical thickness L2 of greater than 80 nm, preferably greater than or equal to 100 nm and less than 280 nm, comprising in this order (starting from the substrate):
   a crystalline (mono or multi)layer, known as an additional layer, based on doped zinc oxide, preferably essentially consisting of a zinc oxide preferably doped with aluminum and/or with gallium (AZO, (A)GZO), of given thickness e₂, directly on the first layer based on silver,
   an optionally amorphous (mono)layer, known as the intermediate layer, based on tin zinc oxide (SnₓZn_{y}O more simply named SnZnO), which is optionally doped (for example Sb) or based on indium zinc oxide (named IZO), or based on indium zinc tin oxide (named ITZO) of given thickness eᵢ, preferably directly on the additional layer,
   a second crystalline contact (mono)layer based on zinc oxide which is preferably doped, preferably essentially consisting of zinc oxide preferably doped with aluminum and/or with gallium (AZO, (A)GZO), second contact layer with a thickness e_{c2} preferably less than 15 nm, better still less than or equal to 10 nm, and preferably at least 3 nm, preferably directly on the intermediate layer,
   a second metallic (mono)layer, based on silver (preferably made of silver), with a given thickness e_{ag2} of less than 20 nm, better still less than or equal to 15 nm, and preferably of at least 3 nm and better still of at least 5 nm, layer preferably directly on the second crystalline contact layer,
   a layer known as an overblocker, directly on the second layer based on silver, which comprises a metallic layer, optionally a metal nitride and/or oxide, based on at least (or made of) one of the following metals: Ti, V, Mn, Fe, Co, Cu, Zn, Zr, Hf, Al, Nb, Ni, Cr, Mo, Ta, W, especially based on an alloy of at least one or two of said materials, with a thickness of less than 3 nm (or even less than 2 nm), preferably based on (or made of) Ti or TiOₓ,
   an electrically conductive overlayer, directly on the overblocker which is preferably dielectric (at least free of silver) and preferably with a final adaptation layer for the output work;
and:
   the sum of the thicknesses e_{c2}+e₂ is at least 30 nm and better still at least 40 nm or even at least 70 nm,
   and, where appropriate, the thickness eᵢ is less than 15 nm, preferably less than or equal to 10 nm, or even in particular for SnZnO, less than or equal to 8 nm, and preferably eᵢ is at least 3 nm.

According to the invention, the following are used for the separating layer:
an additional crystalline layer of zinc oxide, which is a monolayer or is divided into several layers as detailed below, directly on the first layer of silver,
and a sufficient cumulative thickness e_{c2}+e₂ based on a crystalline layer of zinc oxide which may be a source of high roughness.

Now, on removing the first overblocker, contrary to all expectation, it is found that the roughness of the electrode is greatly reduced, before and after annealing. Surprisingly, the first overblocker is neither necessary for protecting the first layer of silver nor for the subsequent chemical protection, but in addition participates toward the creation of roughness in particular for an additional AZO or GZO layer.

Moreover, the measurement of the resistance per square in the stacks of the abovementioned prior art is performed via a contactless technique. This method indicates the contribution of the two layers of silver by assuming a zero vertical resistance between the two layers of silver.

The measurement of the resistance per square according to another, complementary measuring method, known as the four-point method, which measures the effective square R over a lateral length corresponding to the distance between the points (as detailed subsequently), was adequately selected by the Applicant and the vertical resistance of the stacks of the prior art was found to be too high before annealing and most particularly after the annealing performed by the Applicant.

The Applicant also identified that in the stacks of the prior art, it is the intermediate layer of tin zinc oxide, which is very thick between the two layers of silver, which is the cause of the disappointing OLED performance qualities in terms of light efficiency or homogeneity of luminance on large sizes, this layer reducing the vertical electrical conductivity of the electrode.

To ensure a sufficiently low vertical resistance and to conserve L2 within the desired range for the optical performance qualities, e_{c2}+e₂ is large, the additional layer (mono or multilayer) preferably being thicker than 5 nm in the prior art. In addition, the optional intermediate layer is deleted or at the very least of a sufficiently reduced thickness to maintain a low electrical resistance in order thus best to exploit the conductivities of the two layers of Ag for R□. Obviously, one or other dielectric thin layers may be added to the separating layer as long as the vertical resistance remains sufficiently low.

After high-temperature annealing (preferably above 200° C. and better still of at least 250° C.), via the fineness of the intermediate layer (optional) and the choice of the layer(s) of zinc oxide, an even lower electrical resistance is ensured so as thus best to exploit the conductivities of the two layers of Ag for the R□.

Moreover, it was found that after having annealed the stacks of the prior art, their electrical and optical performance qualities were degraded, and were especially accompanied by the formation of dendrites. The Applicant thus observed that, unfortunately, at annealing temperatures above 200° C.:
there was an increase in the resistance per square and absorption, and a reduction in light transmission,
there was appearance, during the annealing, of surface imperfections, referred to hereinbelow as “dendrites”, this local increase in roughness running the risk of being reflected by an increase in short-circuit currents.

Conversely, after the high-temperature annealing (preferably above 200° C. and better still of at least 250° C.) in the stack according to the invention, the fineness of the intermediate layer (or its removal) makes it possible to lower the resistance per square and/or the absorption of the electrode and especially without generating any dendrites in the silver layers.

Even before annealing, the electrical properties of the stack according to the invention are better than those in the prior art in addition to the improvement of the roughness.

The thin intermediate layer, preferably of tin zinc oxide SnZnO, is advantageously used since a layer based on zinc oxide, such as AZO in particular, remains more fragile with regard to chemical processes, especially those involving liquid-route treatments (cleaning, ultrasonication bath, etc.).

Thus, the thickness of this thin intermediate layer according to the invention, preferably of tin zinc oxide SnZnO, is then preferably significantly reduced without being zero. Even thin, it affords an acceptable chemical resistance.

It is also found that this thin intermediate layer has a smoothing function, in particular made of SnZnO, but of second order, the removal of the first overblocker (and the direct deposition of the crystalline layer based on zinc oxide) being much greater.

This thin intermediate layer is made of a different material, at least from the crystallographic point of view, from that of the second contact layer under which it is preferably directly arranged.

This thin intermediate layer may be doped with a metal, SnZnO is preferably doped with antimony (Sb).

As regards this thin intermediate layer preferably chosen based on tin zinc oxide, it is also preferred for it to be free of indium or at least to have a percentage of indium as total weight of metal of less than 10% or even less than 5%. It is preferred for it to consist essentially of tin zinc oxide.

In this intermediate layer chosen based on tin zinc oxide (SnZnO), the total weight percentage of Sn metal preferably ranges from 20% to 90% (and preferably from 80% to 10% for Zn) and in particular from 30% to 80% (and preferably from 70 to 220 for Zn), and the Sn/(Sn+Zn) weight ratio especially preferably ranges from 20% to 90% and in particular from 30% to 80%. And/or it is preferred for the sum of the weight percentages of Sn+Zn to be at least 90% by total weight of metal, better still preferably at least 95% and even at least 97%.

To do this, it is preferred to use a zinc and tin metallic target whose weight percentage (total of the target) of Sn preferably ranges from 20 to 90 (and preferably from 80 to 10 for Zn) and in particular from 30 to 80 for Sn (and preferably from 80 to 30 for Zn) especially, and the ratio Sn/(Sn+Zn) preferably ranges from 20% to 90% and in particular from 30% to 80% and/or the sum of the weight percentages of Sn+Zn of at least 90%, better still preferably of at least 90% and even of at least 95%, or even of at least 97%. The metallic target made of zinc and tin may be doped with a metal, preferentially with antimony (Sb).

The amorphous intermediate layer may alternatively be based on IZO, the weight percentage (total of metal) of In is preferably at least 40%, even at least 60%, and preferably up to 90%, and/or the sum of the weight percentages of In+Zn of at least 85% as total weight of metal or even preferably at least 90% and better still at least 95%.

The amorphous intermediate layer IZO may be doped with aluminum (known as IAZO) and/or gallium (known as IGZO).

In an amorphous intermediate layer made of IGZO, the weight percentage (total of metal) of In is preferably at least 40%, better still 60%, and Ga/(Ga+Zn+In)<10% by weight.

In an amorphous intermediate layer made of IAZO, the weight percentage (total of metal) of In is preferably at least 40%, better still 60%, and Al/(Ga+Zn+In)<10% by weight.

In an alternative amorphous intermediate layer made of ITZO, the weight percentage is at least 2% for Zn and the sum of the weight percentages of Sn+In at least 90% as total weight of metal or even preferably at least 95% and better still at least 98%.

In a first preferred embodiment, at least 60% and preferably at least 80% of the thickness of the separating layer is formed from the thickness e₂ and/or e₂ is greater than or equal to 35 nm, greater than or equal to 45 nm, and better still greater than or equal to 60 nm. The intermediate layer is preferably present.

This choice in particular gives freedom to place closest to the second layer based on silver the thin intermediate layer, preferably of SnZnO, to further increase the chemical resistance, if necessary.

Thus, even more preferentially, especially in this first mode, the additional crystalline layer consists essentially of zinc oxide doped with aluminum and/or gallium (GZO or A(G)ZO) and preferably the second crystalline contact layer consists essentially of zinc oxide preferably doped with aluminum and/or gallium (GZO or A(G)ZO), for example with a thickness e_{c2} of less than or equal to 10 nm, and preferably of at least 3 nm when the thin intermediate layer, preferably based on SnZnO, is inserted.

For any electrode according to the invention, concerning the first and second crystalline contact layers, preference is given in particular to layers free of indium or at least with a percentage of indium as total weight of metal of less than 10% or even 5%, and preferably as already indicated a ZnO oxide which is preferably doped with Al (AZO) and/or Ga (GZO) with the sum of the weight percentages of Zn+Al or Zn+Ga or Zn+Ga+Al or Zn+another dopant preferably chosen from B, Sc or Sb or alternatively from Y, F, V, Si, Ge, Ti, Zr or Hf and even In which is at least 90% as total weight of metal and better still at least 95% and even at least 97%. These two layers are preferably of identical nature (made with the same target, for example) and preferably of the same identical thickness.

For any electrode according to the invention, regarding the additional layer, preference is also given to a layer free of indium or at least with a total weight percentage of metal of less than 10% or even 5%, and consisting essentially of ZnO oxide which is preferably doped with Al (AZO) and/or Ga (GZO or AGZO) with the sum of the weight percentages of Zn+Al or Zn+Ga (or Zn+Ga+Al) or of Zn+another dopant preferably chosen from B, Sc or Sb or alternatively from Y, F, V, Si, Ge, Ti, Zr or Hf and even In of at least 90% or even 95% and even preferably at least 97%.

The additional layer is preferably identical to the first and/or to the second contact layer, for the sake of simplification.

It may be preferred for a layer of AZO according to the invention (contact layer or additional layer) for the weight percentage of aluminum to the sum of the weight percentages of aluminum and zinc, in other words Al/(Al+Zn), to be less than 10% and preferably less than or equal to 5%.

To do this, use may preferably be made of a ceramic target of aluminum oxide and zinc oxide such that the weight percentage of aluminum oxide to the sum of the weight percentages of zinc oxide and aluminum oxide, typically Al₂O₃/(Al₂O₃+ZnO), is less than 14% and preferably less than or equal to 7%.

It may be preferred for a layer of GZO according to the invention (contact layer and/or additional layer) for the weight percentage of gallium to the sum of the weight percentages of zinc and gallium, in other words Ga/(Ga+Zn) to be less than 10% and preferably less than or equal to 5%.

To do this, use may preferably be made of a ceramic target of zinc gallium oxide such that the weight percentage of gallium oxide to the sum of the weight percentages of zinc oxide and gallium oxide, typically Ga₂O₃/(Ga₂O₃+ZnO), is less than 11% and preferably less than or equal to 5%.

It is preferred for the additional layer of zinc oxide, which may be particularly thick, to be deposited from a ceramic target made of zinc oxide which is doped (preferably) with Al and/or Ga—more specifically containing zinc oxide, aluminum oxide and/or gallium oxide—, under an atmosphere of a noble gas (preferably Ar) and as an optional mixture with oxygen in small amount, preferably such that the ratio O₂/(noble gas(es)+O₂) is less than 10% and even better still less than or equal to 5%, which is an amount usually lower than that used during reactive sputtering with a zinc metallic target. Thus, these deposition conditions under a weakly oxygenated atmosphere are less liable to degrade the silver of the first silver layer directly under the additional layer.

It may also be preferred for the second contact layer and even the first contact layer to be deposited from a (same) ceramic target made of zinc oxide which is doped (preferably) with Al and/or Ga—more specifically containing zinc oxide, aluminum oxide and/or gallium oxide—, under an atmosphere of a noble gas (preferably Ar) and as an optional mixture with oxygen in small amount, preferably such that the ratio O₂/(noble gas(es)+O₂) is less than 10% and even better still less than or equal to 5%, an amount usually lower than that used during reactive sputtering with a zinc metallic target.

In the present invention, all the refractive indices are defined at 550 nm.

For example, when the sublayer is a multilayer, for example a bilayer or even a triple layer (which are preferably all dielectric), n1 is the mean index defined by the sum of the index products ni per thickness eᵢ of the layers divided by the sum of the respective thicknesses eᵢ, according to the standard formula n1=Σnᵢeᵢ/Σeᵢ. Naturally, the thickness of the sublayer is then the sum of all the thicknesses.

In the present invention, a layer is dielectric as opposed to a metallic layer, is typically made of metal oxide and/or metal nitride, by extension including silicon. This may be an organic layer, but a mineral layer is preferred.

For the purposes of the invention, a layer is said to be amorphous in the sense that it may be completely amorphous or partially amorphous and thus partially crystalline, but it cannot be completely crystalline, throughout its thickness.

In the present invention, mention is made of a subjacent layer “x”, or a layer “x” under another layer “y”, which naturally implies that the layer “x” is closer to the substrate than the layer “y”.

In the present patent application, when mention is made of a “succession of layers”, of “successive layers” or of a layer located above or below another layer, this always refers to the electrode manufacturing process during which the layers are deposited one after the other onto the transparent substrate. The first layer is thus that which is closest to the substrate, all the “following” layers being those located “on” this first, and “under” layers deposited subsequently.

For the purposes of the present invention, when no precise details are given, the term “layer” should be understood as meaning that there may be a layer made of a single material (monolayer) or several layers (multilayer), each made of a different material. Preferably, the layers made of a defined given material are monolayers.

For the purposes of the present invention, in the absence of any indication, the thickness corresponds to the geometrical thickness.

The electrode according to the invention may extend over a wide surface area, for example a surface area of greater than or equal to 0.02 m² or even greater than or equal to 0.5 m² or greater than or equal to 1 m².

Naturally, the lower electrode is composed of thin layers, and thus of layers each having a thickness of less than 150 nm.

Preferably, the total thickness of the stack of the electrode is less than 300 nm and even 250 nm.

For the purposes of the present invention, for a layer based on an oxide of given metal element(s), the expression “based on” preferably means that the weight proportion of the specified metal element(s) is at least 50% of the total weight of metal and preferably at least 60%.

For the purposes of the present invention, for a layer based on a nitride of given metal element(s), the expression “based on” preferably means that the weight proportion of specified metal element(s) is at least 50% of the total weight of metal and preferably at least 60%.

For the purposes of the invention, in the absence of specific details, the doping of a layer (oxide or nitride) is preferably understood as exposing a presence of the metal dopant in an amount of less than 10% by total weight of metal in the layer.

For the purposes of the present invention, for a layer consisting essentially of an oxide of one or more given metal elements and of optional metal dopants that are expressly defined, the sum of the weight percentages of said elements and optional dopants mentioned is preferably greater than 90% of the total weight of metal and even 95% or even 98%.

For the purposes of the present invention, for a layer consisting essentially of a nitride of one or more given metal elements and of optional metal dopants that are expressly defined, the sum of the weight percentages of said elements and optional dopants mentioned is preferably greater than 90% by total weight of metal and even 95% or even 98%.

By extension, the term metal or metallic (element or dopant) includes silicon and boron, in addition to all the metal elements of the Periodic Table (alkali metals, alkaline-earth metals, transition metals and poor metals).

According to the invention, a layer which consists essentially of a given material may comprise other elements (impurities, etc.) provided that they do not appreciably modify the desired properties of the layer typically by their small amount.

According to the invention, a layer made of a material is synonymous with a layer consisting essentially of this material.

For the purposes of the present invention, the term indium-tin oxide (or tin-doped indium oxide or ITO: indium tin oxide) means a mixed oxide or a mixture obtained from indium(III) oxide (In₂O₃) and tin(IV) oxide (SnO₂), preferably in weight proportions of between 70% and 95% for the first oxide and 5% to 20% for the second oxide. A range of preferred proportions is from 85% to 92% by weight of In₂O₃ and from 8% to 15% by weight of SnO₂. Preferably, the overlayer based on ITO does not comprise any other metal oxide or less than 10% by weight of oxide relative to the total weight.

For the purposes of the invention, in the absence of specific details, the term “thin layer” means a layer with a thickness of less than 10 nm.

The invention does not apply only to stacks comprising only two “functional” silver layers, arranged between three coats, two of which are subjacent coats. It also applies to stacks comprising three functional silver layers alternating with four coats, three of which are subjacent coats, or four functional silver layers alternating with five coats, four of which are subjacent coats.

Preferably, the sublayer may have at least one of the following characteristics:
it may preferably be deposited directly on the substrate, preferably on a sheet of mineral glass,

and/or
it may be a double layer or a triple layer,

and/or
it has a (mean) optical index of greater than or equal to 1.7, even 1.8, in particular for a substrate with an optical index of about 1.5,

and/or
and/or the majority or even all of the layers forming the sublayer (or even all of the layers between the substrate and the first silver metal layer) has an optical index of greater than or equal to 1.7, and even 1.8,
at least the first sublayer is a metal oxide, or even all of the layers of the overlayer are made of metal oxide (excluding the underblocker),
at least the first sublayer is a metal nitride,
the sublayer is free of indium, or at least does not comprise a layer of IZO, ITO,
excluding the first contact layer, the chosen layer(s) are amorphous (both before and after annealing at 300° C.).

As sublayer, in particular for the thin layer that is closest to the substrate (known as the base layer), use may be made of oxides such as niobium oxide (such as Nb₂O₅), zirconium oxide (such as ZrO₂), alumina (such as Al₂O₃), tantalum oxide (such as Ta₂O₅), tin oxide (such as SnO₂), or silicon nitride (Si₃N₄).

In a first preferred embodiment of the sublayer, the sublayer comprises a first sublayer, preferably as a base layer, which is a layer of oxide (more preferentially amorphous) and preferably chosen from one of the following layers:
a layer based on tin zinc oxide (SnZnO, more specifically SnₓZn_{y}O), which is preferably amorphous, for example doped preferably with Sb, and preferably consists essentially of tin zinc oxide, with a thickness e₀ preferably greater than 20 nm, preferably from 30 to 50 nm,
a layer based on titanium oxide (TiOx, preferably TiO₂) which preferably consists essentially of titanium oxide which has the advantage of being a layer with an optical index of greater than 2.3, with a thickness e₀ preferably of greater than 10 nm, preferably from 20 to 40 nm, or a layer optionally containing zirconium (TiₓZr_{y}O referred to more simply as TiZrO),
a layer based on niobium oxide (for example Nb₂O₅) preferably consisting essentially of a layer of niobium oxide (optionally doped) which also has the advantage of being a layer with an optical index of greater than 2.2, with a thickness e₀ preferably greater than 10 nm, preferably from 20 to 40 nm.

For the first sublayer SnZnO, the weight percentage (total of metal) of Sn preferably ranges from 20% to 90% (and preferably from 80% to 10% for Zn) and in particular from 30% to 80%, and in particular the weight ratio Sn/(Sn+Zn) preferably ranges from 20% to 90% and in particular from 30% to 80%. And/or it is preferred for the sum of the weight percentages of Sn+Zn to be at least 90% as total weight of metal, better still at least 95% and preferably even at least 97%.

Its role is, for example, to smooth out, i.e. to limit the roughness of the thin layers (ZnO and Ag) deposited subsequently. It may be doped with a metal, for example with antimony (Sb). The first sublayer of SnZnO is a layer preferably of identical stoichiometry to the intermediate thin layer made of SnZnO.

It is possible to form for the sublayer a multilayer with a layer of zinc tin oxide, a layer of niobium oxide or a layer of titanium oxide, but it is preferred to choose only one of these layers under the first contact layer.

The first sublayer, in particular if it is the base layer, may form an alkali barrier (if necessary) and/or an etch-prevention layer when the electrode is or should be divided into a plurality of (active) zones. The etch-prevention layer in particular serves to protect the substrate in the case of chemical etching or reactive-plasma etching.

Preferably, the electrode according to the invention does not have an amorphous layer of zinc tin oxide or an amorphous layer of titanium oxide with a thickness at least equal to 20 nm or even 40 nm directly under the first contact layer.

In reality, in a preferred configuration of this first embodiment, especially for preventing the formation of dendrites and/or (further) lowering the resistance per square and the absorption after annealing, the first sublayer of oxide, which is preferably amorphous, based on zinc tin oxide in particular, with a thickness preferably greater than 20 nm or even greater than 25 nm, is subjacent to a (dendrite) “barrier” layer which is in contact with the first sublayer, preferably directly under the first crystalline contact layer. The barrier layer is:
based on silicon nitride (SiNₓ, in particular Si₃N₄) and optionally on zirconium SiZrN to increase the refractive index, this layer preferably being doped in particular with aluminum,
or based on silica (SiOₓ, in particular SiO₂) and optionally zirconium, preferably doped,
or optionally made of silicon oxynitride SiₓO_{y}N, or even silicon oxycarbonitride,
or even made of aluminum nitride (AlN), for example with at least 90% by weight or even 95% or even 100% of aluminum nitride in the layer.

Contrary to all expectation, the insertion of the thin barrier layer directly onto the first sublayer of oxide and preferably directly under the first contact layer nevertheless allows good growth and sufficient smoothing of the first contact layer, whereas the use of a smoothing layer made of SnZnO directly under the contact layer AZO, instead of the Si₃N₄ layer, was considered to be essential in the abovementioned prior art.

The thickness e_{b} of the barrier layer is less than 15 nm, preferably less than or equal to 10 nm, and even 9 nm, preferentially from 3 to 8 nm. For silica, this makes it possible to limit the impact of its low optical index.

The sublayer is then preferably a triple layer and especially the following triple layer: (SnZnO or TiOₓ which are optionally doped)/Si(Zr)N or SiO₂ (which are optionally doped)/AZO or (A)GZO.

Preferably, the barrier layer consists essentially of silicon nitride and optionally of zirconium or silica and is optionally doped, in particular Si(Zr)AlN or SiAlO.

The barrier layer more preferentially consists essentially of a layer of silicon nitride which is preferably doped, preferentially with aluminum, or of a layer of silicon zirconium nitride which is preferably doped, preferentially with aluminum.

In a known manner, the silicon nitride is deposited by reactive cathodic sputtering using a metal target (Si) with use of nitrogen as reagent gas.

Aluminum is preferably present in the target (Si) in relatively large amounts, generally ranging from a few percent (at least 1%) to 10% or more of the total weight of metal, typically up to 20%, going beyond standard doping, intended to give the target sufficient conductivity.

In the present invention, an aluminum-doped silicon nitride barrier layer preferably comprises a weight percentage of aluminum to the weight percentage of silicon and aluminum, thus Al/(Si+Al), ranging from 5% to 15%. The aluminum-doped silicon nitride more exactly corresponds to a silicon nitride comprising aluminum (SiAlN).

In the present invention, an aluminum-doped silicon zirconium nitride barrier layer more exactly corresponds to a silicon zirconium nitride comprising aluminum. The weight percentage of zirconium in the barrier layer may be from 10% to 25% of the total weight of metal.

Preferably, in the nitride barrier layer, the sum of the weight percentages of Si+Al or Si+Zr+Al is at least 90% of the total weight of metal, or even preferably 95% by weight or even at least 99%.

The barrier layer alternatively consists essentially of a layer of silica and optionally of zirconia which is preferably doped, preferentially with aluminum.

In a known manner, the silica is deposited by reactive cathodic sputtering using a metal target (Si), preferably doped with use of oxygen as reagent gas.

As for the deposition of silicon nitride, aluminum is preferably present in the target (Si) in relatively large amounts, generally ranging from a few percent (at least 1%) to 10% or more, typically up to 20%, which goes beyond standard doping, intended to give the target sufficient conductivity. In the present invention, an aluminum-doped silicon oxide barrier layer preferably comprises a weight percentage of aluminum to the weight percentage of silicon and aluminum, thus Al/(Si+Al), ranging from 5% to 15%. The aluminum-doped silicon oxide more exactly corresponds to a silicon oxide comprising aluminum.

Preferably, in the oxide barrier layer, the sum of the weight percentages of Si+Al or Si+Zr+Al is at least 90% of the total weight of metal, or even preferably at least 95% or even at least 99%.

The Applicant has discovered that silicon (and optionally zirconium) nitride or silica optionally with zirconia, even at low thickness, made it possible to play a protective role and to efficiently reduce, or even eliminate, the formation of dendrites generated by the thick subjacent layer of SnZnO, without its presence being reflected by a degradation of the electrical and optical properties of the electrode before and after annealing.

It should also be noted that the presence of the thin layer of silicon nitride or of silica does not have a significant impact on the roughness (measured by AFM on 5 μm×5 μm) of the electrode.

The necessary thickness of the barrier layer to reduce or prevent the formation of dendrites generated by the thick SnZnO layer, and to improve the optical and electrical properties, increases with the annealing temperature and time. For annealing temperatures below 450° C. and annealing times of less than 1 h, layer thicknesses of less than 15 nm appear to be sufficient.

In a second embodiment of the sublayer, a layer based on silicon nitride (Si₃N₄) and optionally on zirconium, preferably doped, preferentially with aluminum, is the first thin layer of this sublayer, preferably directly on the transparent substrate and preferably directly on the first contact layer, with a thickness e₀ of greater than 20 nm and better still greater than or equal to 30 nm.

This first layer preferably consists essentially of silicon nitride and optionally of zirconium, and, as already described for the barrier layer, of an aluminum-doped silicon oxide.

Preferably, in the first nitride sublayer, the sum of the weight percentages of Si+Al or Si+Zr+Al is at least 90% of the total weight of metal, preferably 95% or even at least 99%.

The dielectric sublayer is then preferably a double layer Si(Zr)N/AZO or (A)GZO and even more preferentially Si(Zr)N doped Al/AZO or (A)GZO.

Silicon nitride is very rapid to deposit, forms an excellent alkali barrier and can serve as an etch-prevention layer.

When silicon nitride contains zirconium, it is known that its refractive index increases, for example up to 2.2 or even 2.3 as a function of the zirconium content. Thus, its thickness may be adjusted as a function of the refractive index and its thickness may naturally be reduced relative to an SiAlN.

As already indicated, the first and/or second contact layers may preferably be made of zinc oxide which is doped, preferably with Al (AZO), Ga (GZO), or with B, Sc or Sb, or alternatively with Y, F, V, Si, Ge, Ti, Zr or Hf and even with In to facilitate the deposition and a lower electrical resistivity.

It is also possible to choose a first and/or second crystalline contact layer predominantly made of zinc and containing a very small amount of tin which may be likened to doping, referred to hereinbelow as ZnₐSn_{b}O, preferably with the following weight ratio Zn/(Zn+Sn)>90% and better still 95%. In particular, such a layer is preferred with a thickness of less than 10 nm.

The thickness of the first contact layer (AZO, GZO, ZnₐSn_{b}O, etc.) is preferably greater than or equal to 3 nm or even greater than or equal to 5 nm and may also be less than or equal to 20 nm and even more preferentially less than or equal to 10 nm. Preferably, the thickness of the second contact layer (AZO, GZO, ZnₐSn_{b}O etc.) is also greater than or equal to 3 nm, or even greater than or equal to 5 nm and may also be less than or equal to 20 nm and even more preferentially less than or equal to 10 nm.

These crystalline layers are preferred to amorphous layers for better crystallization of the silver. The following are preferentially envisaged under the first silver layer (without specifying the optional doping for the layers other than the contact layers):
first sublayer Si(Zr)N/first contact layer AZO or (A)GZO,
first sublayer Si(Zr)N/first contact layer ZnₐSn_{b}O,
first amorphous sublayer SnZnO of at least 20 nm/barrier layer Si(Zr)N or SiO₂/first contact layer AZO or (A)GZO,
first amorphous sublayer SnZnO of at least 20 nm/barrier layer Si(Zr)N or SiO₂/first contact layer ZnₐSn_{b}O,
first sublayer Ti(Zr)O preferably of at least 10 nm/barrier layer Si(Zr)N or SiO₂/first contact layer AZO or (A)GZO,
first sublayer or Ti(Zr)O preferably of at least 10 nm/barrier layer Si(Zr)N or SiO₂/first contact layer ZnₐSn_{b}O,
first sublayer or Si(Zr)N of at least 20 nm/amorphous SnZnO with a thickness of less than 10 nm/first contact layer AZO or (A)GZO
first sublayer or Si(Zr)N of at least 20 nm/amorphous SnZnO with a thickness of less than 10 nm/first contact layer ZnₐSn_{b}O,
first sublayer Nb₂O₅ preferably of at least 20 nm/preferably barrier layer Si(Zr)Nₓ or SiO₂/first contact layer AZO or (A)GZO,
first sublayer Nb₂O₅ preferably of at least 20 nm/barrier layer Si(Zr)Nₓ or SiO₂/first contact layer ZnₐSn_{b}O,
or more generally: first oxide sublayer preferably of at least 20 nm/preferably barrier layer Si(Zr)N or SiO₂/first contact layer AZO or (A)GZO or even ZnO doped with B, Sc, or Sb or ZnₐSn_{b}O

the barrier layer being less than 15 nm and even preferably less than 10 nm.

Preferably, the separating layer may have at least one of the following characteristics:
it is a triple layer,

and/or
it has a (mean) optical index of greater than or equal to 1.7, even 1.8, and/or
the majority or even all of the layers forming the separating layer have an optical index of greater than or equal to 1.7 and even 1.8,
the separating layer is free of indium or at least does not comprise a layer made of IZO, ITO.

Even if only one intermediate layer is preferred, the multiplicity of similar layers may reduce the roughness.

In a first preferred embodiment, the separating layer comprises (and even consists of) successively, preferably after (without other layers between them) the additional layer which is made of zinc oxide doped with aluminum and/or gallium, the thin amorphous intermediate layer which is made of tin zinc oxide (optionally doped, especially with Sb) preferably with a thickness eᵢ of less than or equal to 8 nm and of at least 3 nm, the second contact layer which is made of zinc oxide doped with aluminum and/or gallium preferably with the sum of the thicknesses e_{c2}+e₂ of at least 50 nm, better still at least 70 nm and less than 120 nm and preferentially the separating layer comprises (and even consists of) AZO/SnZnO/AZO or GZO/SnZnO/GZO preferably with the sum of the thicknesses e_{c2}+e₂ of at least 50 nm, better still at least 70 nm and less than 120 nm.

In one embodiment, in addition to the thin intermediate layer, one or more other amorphous layers each with a thickness eᵤ of less than 15 nm and better still 10 nm, divides the additional (multi)layer into several “buffer (mono)layers” (at least one or even two buffer layers and preferably less than 5 buffer layers) each with a thickness e₂ᵢ (which are different or equal), preferably evenly spaced layers. Each other amorphous layer being based on a same oxide as that of the intermediate layer and preferably optionally doped zinc tin oxide.

Needless to say, the sum of the thicknesses of the buffer layers forming the additional layer, Σe₂ᵢ is equal to e₂, and the relationship e_{c2}+e₂ more precisely corresponds to e_{c2}+Σe₂ᵢ.

The other amorphous layer(s) preferably of SnZnO are preferably of identical nature to the thin amorphous layer preferably of SnZnO.

In a second preferred embodiment, the separating layer is a crystalline monolayer (directly on the first silver layer) and preferably consists essentially of zinc oxide which is doped, preferably with aluminum and/or gallium, e₂ preferably being at least 50 nm, better still at least 70 nm and better still at least 80 nm and preferably less than 120 nm. Said monolayer thus forms both the additional layer and the second contact layer.

Moreover, the separating layer according to the invention has a sufficiently low vertical resistance between the two silver layers.

It may preferably be envisaged that between the first and second silver layers, each layer (other than the optional thin intermediate layer) has an electrical resistivity of less than or equal to 10³ ohm·cm, preferably less than or equal to 1 ohm·cm or even less than or equal to 10⁻² ohm·cm.

A layer of zinc oxide adequately doped with a metal has a sufficiently low vertical resistance, which is important for the additional layer and the second contact layer.

A doped zinc oxide layer and most particularly a layer of AZO or GZO has a low vertical electrical resistance even at thicknesses beyond 50 nm. Typically, an AZO layer has a resistivity of 10⁻² ohm·cm or even 10⁻³ ohm·cm or even goes down to 10⁻⁴ ohm·cm dependent on the deposition method and the post-treatments, as evidenced by the article entitled “Transparent conducting oxide semiconductors for transparent electrodes” Semicond. Sci. Technol. 20 (2005) S35-S44.

For illustrative purposes, an ITO layer typically has a resistivity of 210⁻⁴ ohm·cm to 10⁻³ ohm·cm.

It is also possible to choose an additional crystalline layer based on zinc oxide, predominantly made of zinc and containing a very small amount of tin which may be likened to doping, referred to hereinbelow as ZnₐSn_{b}O, preferably with the following weight ratio Zn/(Zn+Sn)>90%, better still ≧95%.

In point of fact, the additional crystalline layer may be a zinc oxide “doped” with Sn and/or with indium, i.e. containing tin and/or indium.

As already stated, the R□ of the electrode may be measured via the contactless method, of electromagnetic type, referred to here as R□ₑₗₘ. This measuring technique makes it possible to measure the conductivity of the two layers of Ag (or of N>2 layers of silver) independently of the conductivity of the separating layer. This method is the one used in the prior art.

The R□ is also measured via the 4-point method, known as R□₄ₚ with a distance between the points of 3 millimeters, even if the lateral distance of an OLED is generally at least 5 to 10 cm. If the vertical resistance between the two layers of Ag is large relative to the lateral resistance between the measuring points, in contact with the surface of the ITO layer, R□₄ₚ is greater than R□ₑₗₘ.

Now, commercial OLEDs are intended to be larger than 5×5 cm², or even 10×10 cm², or even 20×20 cm². In these cases, the lateral distance is much greater than that used in the 4-point measurement, and the first silver layer is capable of contributing to the conductivity of the electrode if R_{Vert} is sufficiently low.

Thus, preferably, the electrode according to the invention has, in particular comprising only two silver layers, a difference in absolute value of R□₄ₚ-R□ₑₗₘ of less than 0.7×R□ₑₗₘ, preferably less than 0.4×R□ₑₗₘ and even less than 0.2×R□ₑₗₘ, R□ₑₗₘ being the measurement via the electromagnetic contactless method (for example Nagy instrument) and R□₄ₚ being the measurement via the 4-point method (for example Napson instrument) with a distance of 3 mm between the points.

Independently of knowing whether the size of the OLED allows all the Ag layers (or at least the last two Ag layers) of the stack to contribute toward the transportation of carriers, the vertical resistance must be as low as possible, since it induces an increase in the necessary power to be delivered, and thus a reduction in the light efficiency (lm/W).

The substrate according to the invention coated with the lower electrode has low roughness (on the overlayer).

The substrate according to the invention coated with the lower electrode preferably has, on the overlayer, a roughness R_{q}, which is a well known parameter, of less than or equal to 5 nm, better still 3 nm, preferably even less than or equal to 2 nm, so as to avoid spike effects which drastically reduce the service life and the reliability especially of the OLED.

The substrate according to the invention coated with the lower electrode preferably has, on the overlayer, a roughness Rₘₐₓ, which is known per se, of less than or equal to 20 nm, and preferably even less than or equal to 15 nm.

The parameters may be measured in various ways, preferably by atomic force microscopy. The measurement is generally performed on 1 to 30 square micrometers by atomic force microscopy.

Preferably, to limit the absorption or roughness and/or to limit the vertical resistance and/or to minimize the dendrites or to promote the injection of current and/or to limit the operating voltage value, the presence of certain oxide or nitride layers is avoided.

Thus, it is preferred to exclude over the first silver layer (below the second layer and/or above the second layer) one or more layers based on silicon nitride, silicon oxide, silicon oxynitride, silicon oxycarbide, based on silicon oxycarbonitride, or alternatively based on titanium oxide with a thickness of greater than or equal to 15 nm or even greater than 10 nm.

The present invention does not cover multilayer structures whose last layer (the outermost layer) is a nonconductive layer, such as a layer made of silicon carbide, or preferably at the very least a nonconductive layer that is thick enough to prevent vertical conduction of silver to the layer containing an organic light-emitting substance. The reason for this is that such structures would be unsuitable for use as OLED electrode.

Preferably, the overlayer may have at least one of the following characteristics:
it may be a monolayer, a double layer, a triple layer,
at least the first layer (excluding the overblocker) is a metal oxide, or even all of the layers of the overlayer are made of metal oxide,
all of the layers of the overlayer have a thickness of less than or equal to 120 nm, or even 80 nm,
it may have a (mean) index greater than that of the substrate, for example greater than or equal to 1.8.

The overlayer is preferably based on thin layer(s), which are especially mineral.

Moreover, to promote the injection of current and/or to limit the value of the operating voltage, it may preferably be envisaged for the overlayer to consist of layer(s) (excluding the thin blocking layer described subsequently) with an electrical resistivity of less than or equal to 10² ohm·cm, preferably less than or equal to 1 ohm·cm, or even less than or equal to 10⁻² ohm·cm.

The overlayer is preferably free of layer(s) with a thickness of greater than 10 nm or even 5 nm based on silicon nitride (Si₃N₄) or based on silica (SiO₂). Any layer forming etch prevention by its nature or even its thickness (TiO₂, SnO₂, etc.) may also be avoided.

The overlayer according to the invention is preferably based on at least one of the following metal oxides, which are optionally doped: tin oxide, indium oxide, zinc oxide (optionally sub-stoichiometric), molybdenum, tungsten or vanadium oxide.

This overlayer may in particular be made of tin oxide optionally doped with F, Sb, or made of zinc oxide optionally doped with aluminum, or may be optionally based on a mixed oxide, especially an indium tin oxide (ITO), an indium zinc oxide (IZO) or a tin zinc oxide SnZnO.

This overlayer, in particular for ITO, IZO (generally the last layer) or based on ZnO may preferably have a thickness e₃ of less than or equal to 100 nm, or 80 nm, for example between 10 or 15 nm and 60 nm.

The ITO layer is preferentially super-stoichiometric in oxygen to reduce its absorption (deposited under oxygen-rich conditions).

Generally, the final layer based on silver (which is preferably the second) is covered with a thin additional layer having an output work higher than silver, typically ITO. A layer for adapting the output work may have, for example, an output work Ws from 4.5 eV and preferably greater than or equal to 5 eV.

Thus, in a preferred embodiment, the overlayer comprises, preferably as the last layer, especially as the layer for adapting the output work, a layer which is based on (preferably essentially consisting of) at least one of the following metal oxides, which are optionally doped: indium oxide, zinc oxide optionally sub-stoichiometric, molybdenum oxide (MoO₃), tungsten oxide (WO₃), vanadium oxide (V₂O₆), indium tin oxide (ITO), indium zinc oxide (IZO) or tin zinc oxide SnZnO, and the overlayer preferably has a thickness of less than or equal to 50 nm or even 40 nm or even 30 nm.

The overlayer may comprise a final layer, which is based on a thin metal layer (less conductive than silver), especially based on nickel, platinum or palladium, for example with a thickness of less than or equal to 5 nm, especially from 1 to 2 nm, and preferably separated from the second silver metal layer (or overblocker) by a subjacent layer made of a simple or mixed metal oxide such as tin zinc oxide (SnZnO) or ZnO or even ITO.

The overlayer may comprise as a final dielectric layer a layer with a thickness of less than 5 nm, or even 2.5 nm and of at least 0.5 nm, or even 1 nm, chosen from a nitride, an oxide, a carbide, an oxynitride or an oxycarbide, especially of Ti, Zr, Ni or NiCr.

However, the preferred layer is ITO, MoO₃, WO₃, V₂O₆ or even IZO as the last, and even as the only layer of the overlayer.

The lower electrode according to the invention is easy to manufacture, in particular by selecting for the materials of the stack materials that can be deposited at room temperature. Even more preferentially, the majority of or even all the layers of the stack are deposited under vacuum (preferably successively), preferably by cathodic sputtering optionally magnetron-assisted, allowing significant productivity gains.

A preferred stack is one comprising only two (pure) silver layers, the separating layer as three layers, and the overlayer as one, or even two layers.

The overblocker forms a protective layer or even a “sacrificial” layer which makes it possible to prevent impairment of the metal of the metal layer (the second), especially in one and/or the other of the following configurations:
if the layer mounted on the metal layer (the second) is deposited using a reactive plasma (oxygen, nitrogen, etc.), for example if the oxide layer mounted thereon is deposited by cathodic sputtering,
if the composition of the layer mounted on the metal layer (the second) is capable of varying during the industrial manufacture (change of the deposition conditions such as erosion of a target, etc.) especially if the stoichiometry of a layer of oxide and/or nitride type changes, then modifying the quality of the metal layer and thus the properties of the electrode (square resistance, light transmission, etc.),
when the electrode coating undergoes, subsequent to deposition, a heat treatment or cleaning, or a chemical treatment.

This protective layer significantly improves the reproducibility of the electrical and optical properties of the electrode. This is very important for an industrial approach in which only a low dispersion of the properties of the electrodes is acceptable.

For example, the overblocker may consist of a layer based on niobium, tantalum, titanium, chromium or nickel or an alloy of at least two of said metals, such as a nickel-chromium alloy.

It is in particular preferred for the overblocker based on a metal chosen from niobium Nb, tantalum Ta, titanium Ti, chromium Cr or nickel Ni or an alloy of at least two of these metals, especially an alloy of niobium and tantalum (Nb/Ta), of niobium and chromium (Nb/Cr) or of tantalum and chromium (Ta/Cr) or of nickel and chromium (Ni/Cr). This type of layer based on at least one metal has a particularly large “getter” effect.

The overblocker may be readily manufactured without impairing the metal layer (the second). This metal layer may preferably be deposited under an inert atmosphere (i.e. without deliberate introduction of oxygen or nitrogen) consisting of a noble gas (He, Ne, Xe, Ar or Kr). It is not excluded or inconveniencing for the surface of this metal layer to be oxidized during the subsequent deposition of a layer based on metal oxide.

However, for the use of the metal overblocker, the thickness of the metal layer and thus the light absorption should be limited so as to conserve a sufficient light transmission for the transparent electrodes.

The overblocker may be partially oxidized. This layer is deposited in nonmetallic form and is therefore not deposited in stoichiometric form, but in sub-stoichiometric form, of the type MOₓ, where M represents the material and x is a number less than the stoichiometry of the oxide of the material or of the type MNOₓ for an oxide of two materials M and N (or more). Examples that may be mentioned include TiOₓ and NiCrOₓ.

x is preferably between 0.75 times and 0.99 times the normal stoichiometry of the oxide. For a monoxide, it is especially possible to choose x between 0.5 and 0.98 and for a dioxide, x between 1.5 and 1.98.

In a particular variant, the overblocker is based on TiOₓ, and x may in particular be such that 1.5≦x≦1.98 or 1.5<x<1.7, or even 1.7≦x≦1.95.

The overblocker may be partially nitridized. It is therefore not deposited in stoichiometric form, but in sub-stoichiometric form, of the type MN_{y}, where M represents the material and y is a number less than the stoichiometry of the nitride of the material, y is preferably between 0.75 times and 0.99 times the normal stoichiometry of the nitride.

Similarly, the overblocker may also be partially oxynitridized.

The oxidized and/or nitridized overblocker may be readily manufactured without impairing the silver layer. It is preferably deposited from a ceramic target, under a non-oxidizing atmosphere preferably consisting of a noble gas (He, Ne, Xe, Ar or Kr).

The overblocker may preferentially be made of sub-stoichiometric nitride and/or oxide for further reproducibility of the electrical and optical properties of the electrode.

As sub-stoichiometric metal nitride, a layer made of chromium nitride CrNₓ or of titanium nitride TiNₓ or of a nitride of several metals such as NiCrNₓ may also be chosen.

The overblocker may have an oxidization gradient, for example M(N)Oₓᵢ with xᵢ variable, the part of the blocking layer in contact with the metal layer is less oxidized than the part of this layer that is the most remote from the metal layer by using a particular deposition atmosphere.

The overblocker is most particularly made of titanium (Ti, TiOₓ) which alone protects the silver layers during the steps of OLED manufacturing processes and absorbs little, especially after heat treatment.

Provision may also be made for one or two very thin coats known as “underblocking coats” or underblockers, placed directly over the first and/or second metal layer based on silver, for example those mentioned above for the overblocker. The underblocking coat subjacent to a metal layer, in the direction of the substrate, is an attachment, nucleating and/or protective coat.

Preferably, the first and/or second metal layer may be made of silver alloyed or doped with at least one other material, preferably chosen from: Au, Pd, Al, Pt, Cu, Zn, Cd, In, Si, Zr, Mo, Ni, Cr, Mg, Mn, Co, Sn, and is especially based on an alloy of silver and palladium and/or gold and/or copper, to improve the moisture resistance of silver.

The first and second silver layers may be made of the same silver material with the same optional alloy or doping.

In a preferred design, the first and second metal layers based on silver (i.e. on pure silver or as a metal alloy predominantly containing silver) with:
the thickness e_{ag1} is less than or equal to 15 nm, better still less than or equal to 13 nm and preferably from 5 to 10 nm,

and/or
the thickness e_{ag2} is less than or equal to 15 nm, better still less than or equal to 13 nm and preferably from 5 to 10 nm,

and/or
the thickness e_{ag1} is greater than the thickness e₂ (from 1 to 10 nanometers),
the thickness e_{ag2} is greater than the thickness e_{ag1} (from 1 to 10 nanometers).

An astute choice of the optical thicknesses L1 and L2 makes it possible first to adjust the optical cavity so as to optimize the efficacy of the OLED and also significantly to reduce the colorimetric variation as a function of the observation angle. Preferably
L1 ranges from 100 nm to 120 nm,
and/or L2 ranges from 140 nm to 240 nm, and even 220 nm,
and/or the sum of the thicknesses e_{ag1}+e_{ag2} of the first and second metal layers is less than or equal to 30 nm, preferably less than or equal to 25 nm or even less than or equal to 20 nm to reduce the absorption.

The lower electrode may preferably be directly on the substrate, the substrate with electrode being free of internal light extraction element.

The substrate with electrode may comprise an external light extraction element that is already known per se, such as:
addition of a film (self-supporting) or deposition of a diffusing layer for volume-based diffusion,
formation of a system of microlenses, etc.

As already mentioned, the increase in the thickness of the additional layer (with an intermediate layer and a second thin contact layer) may itself also make it possible to obtain a sufficient thickness L2.

The various preferred embodiments mentioned above may of course be combined together. All the possible combinations are not explicitly described in the present text so as not to emburden it unnecessarily. A few examples of particularly preferred stacks are given below (with optional doping not restated for the layers other than the contact layers):
first sublayer (preferably amorphous) based on oxide preferably of at least 20 nm/barrier layer/first contact layer ZnO (doped)/Ag/additional crystalline layer ZnO (doped)/amorphous intermediate layer/second contact layer ZnO (doped)/Ag/overblocker/overlayer preferably ITO, MoO₃, WO₃, V₂O₅, or even AZO or ZnₐSn_{b}O, optionally mounted on a layer (TiN, etc.) of not more than 5 nm, better still not more than 3 nm or 2 nm,
first amorphous sublayer SnZnO of at least 20 nm/barrier layer/first contact layer ZnO (doped)/Ag/additional crystalline layer doped ZnO (/intermediate amorphous layer/) second contact layer doped ZnO/Ag/overblocker/overlayer preferably ITO, MoO₃, WO₃, V₂O₅ or even AZO or ZnₐSn_{b}O (crystalline), on which is optionally mounted a layer (TiN, etc.) of not more than 5 nm, better still not more than 3 nm or 2 nm,
first amorphous sublayer Ti(Zr)O preferably of at least 10 nm/barrier layer/first contact layer ZnO (doped)/Ag/additional crystalline layer doped ZnO (/intermediate amorphous layer/) second contact layer doped ZnO/Ag/overblocker/overlayer preferably ITO, MoO₃, WO₃, V₂O₅ or even AZO or ZnSnO (crystalline), on which is optionally mounted a layer (TIN, etc.) of not more than 5 nm, better still not more than 3 nm or 2 nm,
first sublayer Nb₂O₅ preferably of at least 20 nm/preferably barrier layer/first contact layer ZnO (doped)/Ag/additional crystalline layer doped ZnO/(intermediate amorphous layer/) second contact layer doped ZnO/Ag/overblocker/overlayer preferably ITO, MoO₃, WO₃, V₂O₅ or even AZO or ZnSnO (crystalline), on which is optionally mounted a layer (TiN, etc.), of not more than 5 nm, better still not more than 3 nm or 2 nm,
first sublayer Si(Zr)N of at least 20 nm (/amorphous layer SnZnO with a thickness of less than 10 nm/) first contact layer ZnO (doped)/Ag/additional crystalline layer doped ZnO (/intermediate amorphous layer/) second contact layer doped ZnO/Ag/overblocker/overlayer preferably ITO, MoO₃, WO₃ V₂O₅ or even AZO or ZnSnO (crystalline), on which is optionally mounted a layer (TiN, etc.) of not more than 5 nm, better still not more than 3 nm or 2 nm.

In a preferred embodiment both for the excellent electrical properties (especially the vertical conductivity) and the chemical resistance, the stack consists of one of the following stacks (with optional doping not respecified for the layers other than the contact layers):
first oxide sublayer which is preferably amorphous of at least 20 nm/barrier layer Si(Zr)N or SiO₂/first contact layer AZO or (A)GZO/Ag/additional crystalline layer AZO or (A)GZO/intermediate amorphous layer/second contact layer AZO or (A)GZO/Ag/overblocker/overlayer preferably ITO, MoO₃, WO₃, V₂O₅ or even AZO or ZnSnO (crystalline), on which is optionally mounted a layer (TiN, etc.) of not more than 5 nm, better still not more than 3 nm or 2 nm,
first amorphous sublayer SnZnO preferably of at least 20 nm/barrier layer Si(Zr)N or SiO₂/first contact layer AZO or (A)GZO/Ag/additional crystalline layer AZO or (A)GZO/intermediate amorphous layer/second contact layer AZO or (A)GZO/Ag/overblocker/overlayer preferably ITO, MoO₃, WO₃, V₂O₅ or even AZO or ZnSnO (crystalline), on which is optionally mounted a layer (TiN, etc.) of not more than 5 nm, better still not more than 3 nm or 2 nm,
first amorphous sublayer SnZnO preferably of at least 20 nm or TiO₂/barrier layer Si(Zr)N or SiO₂ preferably of at least 10 nm/first contact layer AZO or (A)GZO/Ag/additional crystalline layer AZO or (A)GZO/intermediate amorphous layer/second contact layer AZO or (A)GZO/Ag/overblocker/overlayer preferably ITO, MoO₃, WO₃, V₂O₅ or even AZO or ZnSnO (crystalline), on which is optionally mounted a layer (TiN, etc.) of not more than 5 nm, better still not more than 3 nm or 2 nm,
first sublayer Nb₂O₅ preferably of at least 20 nm/preferably barrier layer Si(Zr)N or SiO₂/first contact layer AZO or (A)GZO/Ag/additional crystalline layer AZO or (A)GZO/intermediate amorphous layer/second contact layer AZO or (A)GZO/Ag/overblocker/overlayer preferably ITO, MoO₃, WO₃ V₂O₅ or even AZO or ZnSnO (crystalline), on which is optionally mounted a layer (TiN, etc.) of not more than 5 nm, better still not more than 3 nm or 2 nm,
first sublayer Si(Zr)N/(amorphous layer SnZnO)/first contact layer AZO or (A)GZO/Ag/additional crystalline layer AZO or (A)GZO/intermediate amorphous layer/second contact layer AZO or (A)GZO/Ag/overblocker/overlayer preferably ITO, MoO₃, WO₃, V₂O₅ or even AZO or ZnSnO (crystalline), on which is optionally mounted a layer (TiN, etc.) of not more than 5 nm, better still not more than 3 nm or 2 nm,

and even more preferentially:
first amorphous sublayer SnZnO/barrier layer Si(Zr)N or SiO₂/first contact layer AZO or (A)GZO/Ag/additional crystalline layer AZO or (A)GZO/intermediate amorphous layer SnZnO/second contact layer AZO or (A)GZO/Ag/overblocker preferably Ti/overlayer preferably ITO preferably as the last layer,
first amorphous sublayer SnZnO or TiO₂/barrier layer Si(Zr)N or SiO₂/first contact layer AZO or (A)GZO/Ag/additional crystalline layer AZO or (A)GZO/intermediate amorphous layer SnZnO/second contact layer AZO or (A)GZO/Ag/overblocker preferably Ti/overlayer preferably ITO preferably as the last layer,
first sublayer Nb₂O₅ (/barrier layer Si(Zr)N or SiO₂)/first contact layer AZO or (A)GZO/Ag/additional crystalline layer AZO or (A)GZO/intermediate amorphous layer SnZnO/second contact layer AZO or (A)GZO/Ag/overblocker preferably Ti/overlayer preferably ITO, preferably as the last layer,
first sublayer Si(Zr)N/(amorphous layer SnZnO with a thickness of less than 10 nm)/first contact layer AZO or (A)GZO/Ag/additional crystalline layer AZO or (A)GZO/intermediate amorphous layer SnZnO/second contact layer AZO or (A)GZO/Ag/overblocker preferably Ti/overlayer preferably ITO, preferably as the last layer.

More preferably, the contact layers and the additional layer are all made of AZO or all made of GZO and the barrier layer is made of Si(Zr)N or even of silica and contains aluminum, the barrier layer being less than 15 nm and even preferably less than 10 nm.

It is understood that after annealing and/or deposition of the subjacent oxide layer, each overblocker (preferably titanium, or even NiCr) may be at least partially oxidized.

As GZO proves to be more chemically inert than AZO, it is possible, when a layer of GZO is chosen for the additional layer (and the second contact layer), at will to maintain the thin intermediate layer as a reinforcement or alternatively not to insert it.

Preferably, especially for all the abovementioned modes, the stack comprises only two silver layers.

However, since the stack comprises, for example, one or more other silver layers, between the second silver layer and another silver layer and/or between each other silver layer, the following are directly added in this order onto the middle silver layer: another additional layer based on ZnO, which is preferably doped, preferably with a thickness of greater than or equal to 40 nm, another optional amorphous intermediate layer based on SnZnO or based on indium zinc oxide or based on indium zinc tin oxide with a thickness of less than 15 nm, another crystalline contact layer based on ZnO preferably with a thickness of less than 10 nm.

To further reduce the cost of the lower electrode, it may be preferred for the total thickness of material containing (preferably predominantly, i.e. with a weight percentage of indium of greater than or equal to 50%) indium of this electrode to be less than or equal to 80 nm, or even less than or equal to 60 nm. Mention may be made, for example, of ITO, IZO as layer(s) for which it is preferable to limit the thicknesses.

Below the overlayer, the electrode is in particular preferably free of layer(s) comprising indium, with at least a weight percentage of indium of greater than or equal to 50% of the total weight of metal.

A subject of the present invention is also an organic light-emitting diode device (OLED) comprising at least one lower electrode according to the present invention as described above. This electrode preferably acts as the anode. The OLED then comprises:
an anode formed by the electrode of the present invention,
a layer containing an organic light-emitting substance, and
a cathode.

The conductive support as defined previously may be used for an OLED device comprising at least one electrode zone (filled) with a size of greater than or equal to 1×1 cm², or even 5×5 cm², even 10×10 cm² and greater.

A light-emitting system (OLED system) with the organic layer above the lower electrode as defined previously may be envisaged to emit polychromatic radiation defined at 0° via coordinates (x1, y1) in the CIE XYZ 1931 colorimetric diagram, coordinates thus given for normal radiation.

The OLED device may be a device with bottom emission and optionally also with top emission depending on whether the cathode is reflective or semi-reflective, or even transparent (especially of TL comparable to the anode typically from 60% and preferably greater than or equal to 80%). For the cathode, use may be made of a thin metal layer known as “TCC” (transparent conductive coating), for example made of Ag, Al, Pd, Cu, Pd, Pt, In, Mo or Au and typically with a thickness of between 5 and 150 nm as a function of the desired light transmission/reflection. For example, a silver layer is transparent below 15 nm, and opaque at and above 40 nm.

In addition, it may be advantageous to add a coat which has a given functionality on the face opposite the substrate bearing the electrode according to the invention or on an additional substrate. It may be an anti-fogging layer (with the aid of a hydrophilic layer), antisoiling layer (photocatalytic coat comprising TiO₂ at least partially crystallized in anatase form), or alternatively an antireflection stack, for instance Si₃N₄/SiO₂/Si₃N₄/SiO₂ or alternatively a UV filter, for instance a layer of titanium oxide (TiO₂). It may also be one or more luminophore layers, a mirror layer, at least one light extraction diffusing zone.

The invention also relates to the various applications that may be found for these OLED devices, forming one or more transparent and/or reflective luminous surfaces (mirror function) placed both externally and internally.

The device may form (alternative or cumulative choice) a lighting, decorative, architectural, etc. system, a signaling display sign—for example of the drawing, logo or alphanumeric signaling type, especially an emergency exit sign.

The OLED device may be arranged to produce a uniform polychromatic light, especially for homogeneous lighting, or to produce different lighting zones, of the same intensity or of different intensity.

When the electrodes and the organic structure of the OLED system are chosen to be transparent, it is especially possible to make a lighting window. Improvement of the lighting of the room is then not achieved to the detriment of the light transmission. By also limiting the light reflection especially on the exterior side of the lighting window, this also makes it possible to control the level of reflection, for example to satisfy the anti-glare standards in force for building facades.

More broadly, the OLED device, which is especially partly or totally transparent, may be:
intended for building, such as an exterior lighting glazing, an interior lighting partition or a (part of a) luminous glazed door which is especially a sliding door,
intended for a transportation vehicle, such as a sunroof, a (part of a) luminous side window, an interior luminous partition of a terrestrial, aquatic or aerial vehicle (car, lorry, train, aircraft, boat, etc.),
intended for urban or professional furnishings such as a bus shelter panel, a wall of a display case, a jewelry display case or a shop window, a greenhouse pane, or a lighting floor slab,
intended for interior furnishing, a shelf or furniture component, a façade of a piece of furniture, a lighting floor slab, a ceiling tile, a lighting refrigerator tray, an aquarium wall.

To form a lighting mirror, the cathode may be reflective.

It may also be a mirror. The light panel may serve for lighting a bathroom wall or a kitchen work surface, or may be a ceiling tile.

OLEDs are generally dissociated into two major families according to the organic material used.

If the light-emitting layers are small molecules, they are referred to as SM-OLEDs (Small Molecule Organic Light Emitting Diodes).

In general, the structure of an SM-OLED consists of a stack of injection layers with holes or “HIL” for “Hole Injection Layer”, or “HTL” for “Hole Transporting Layer”, an emissive layer, or an electron transporting layer or “ETL”.

Examples of organic light-emitting stacks are described, for example, in the document entitled “Four wavelength white organic light emitting diodes using 4,4′-bis [carbazoyl-(9)]-stilbene as a deep blue emissive layer” from C. H. Jeong et al., published in Organics Electronics 8 (2007) pages 683-689.

If the organic light-emitting layers are polymers, they are referred to as PLEDs (Polymer Light Emitting Diodes).

The organic layer(s) of OLEDs generally have an index starting from 1.8 or even beyond (1.9 and even more).

Preferably, the OLED device may comprise a more or less thick OLED system, for example between 50 and 350 nm.

The electrode is suitable for tandem OLEDs described, for example, in the publication entitled “Stacked white organic light-emitting devices based on a combination of fluorescent and phosphorent emitter” by H. Kanno et al., Applied Phys Lett 89 023503 (2006).

OLED devices exist comprising an “HTL” layer (Hole Transport Layer) that is strongly doped, as described in U.S. Pat. No. 7,274,141, for which the high output work of the final layer of the overlayer is unimportant.

A subject of the present invention is also a process for manufacturing the electrode of the conductive support according to the invention and even an OLED device incorporating it. This process obviously comprises the deposition of the successive layers constituting the electrode described above.

The deposition of all these layers preferably takes place under vacuum, even more preferentially by physical vapor phase deposition and better still by cathodic sputtering (magnetron).

Preference is given in particular to a process for manufacturing the electrode of the conductive support according to the invention (as described previously) in which:
the additional layer deposited on the first silver layer is made of zinc oxide which is doped preferably with aluminum and/or gallium and is prepared by cathodic sputtering (magnetron) using a ceramic target of zinc oxide which is doped preferably with aluminum and/or gallium, with, during the deposition, an (optional) oxygen content of greater than or equal to 0% and less than 10% and better still less than or equal to 5% and a content of noble gas(es) (preferably argon) of at least 90% and better still of at least 95%.

And preferably:
preferably, when the second contact layer is (directly) on the intermediate layer, the second contact layer is made of zinc oxide doped preferably with aluminum and/or gallium, and is prepared by magnetron cathodic sputtering using a ceramic target of zinc oxide doped preferably with aluminum and/or gallium, with, during the deposition, an oxygen content of greater than or equal to 0% and less than 10% and better still less than or equal to 5% and a content of noble gas(es) (preferably argon) of at least 90% and better still of at least 95%,
preferably, the first contact layer is prepared by cathodic sputtering using a ceramic target, preferably of zinc oxide preferably doped with aluminum and/or gallium, with, during the deposition, an (optional) oxygen content of less than 10% and preferably less than or equal to 5% and a content of noble gas(es) of at least 90% and preferably of at least 95%,
and even more preferentially the second contact layer (and the first contact layer) and the additional layer are prepared by magnetron cathodic sputtering using the same target of zinc oxide doped preferably with aluminum and/or gallium, with, during the deposition, an oxygen content of less than 10% and better still less than or equal to 5% and a content of noble gas(es) (preferably argon) of at least 90% and better still of at least 95%.

The ceramic target and this low content of oxygen (optionally present) during the deposition of the additional layer are chosen to preserve as much as possible the first silver layer from the oxygen, during the deposition of the additional layer.

A ceramic target and a low oxygen content are also preferred for the first and the second contact layer so as to prevent any excess oxygen which might diffuse into the silver layers (preferably directly onto the contact layers) during annealing and thus to prevent any degradation of the optical and electrical properties and even to make it possible to improve the electrical properties via better crystallinity of the silver.

Preferably, for the overlayer, each oxide layer is prepared by cathodic sputtering (magnetron) using a ceramic target, with, during the deposition, a limited content of oxygen (optional), for example greater than or equal to 0% and less than 10% and better still less than 5% and a content of noble gas(es) (preferably argon) of at least 90% and better still at least 95%. In particular, the overlayer comprises or even consists of an ITO layer prepared by cathodic sputtering (magnetron) using a ceramic target of indium tin oxide, with, during the deposition, an (optional) oxygen content of less than 10% and better still less than 5%.

The process for manufacturing the OLED according to the invention also comprises a step of heating the transparent electrode to a temperature above 180° C., preferably above 200° C., better still greater than or equal to 230° C., in particular from 250° C. to 400° C. or even up to 450° C., and ideally from 250 to 350° C., for a time preferably of between 5 minutes and 120 minutes and in particular between 15 and 90 minutes.

During this heating step (annealing), the electrode of the present invention undergoes:
a further reduced vertical resistance,
and even a noteworthy reduction of the resistance per square and of the absorption.

The invention advantageously proposes an electrode which is suitable for annealing (to optimize its properties) or which has undergone (at least one) annealing. To diagnose whether an electrode is suitable for annealing (first or additional annealing), annealing is performed at 300° C. for one hour and the optical and electrical properties are measured as mentioned previously.

The substrate may be flat or curved, and also rigid, flexible or semi-flexible.

Its main faces may be rectangular, square or even of any other shape (round, oval, polygonal, etc.). This substrate may be of large size, for example with a surface area of greater than 0.02 m², or even 0.5 m² or 1 m² and with a lower electrode (optionally divided into several zones known as electrode surfaces) occupying substantially the surface (plus or minus the structuring zones and/or plus or minus the edge zones).

The substrate is substantially transparent. It may have a light transmission T_{L} of greater than or equal to 70%, preferably greater than or equal to 80% or even greater than or even to 90%.

The substrate may be mineral or plastic.

The substrate may especially be a layer based on polyethylene terephthalate (PET), polyethylene naphthalate (PEN), polycarbonate, polyurethane, polymethyl methacrylate, polyimide, polyimide, fluoropolymer such as ethylene-tetrafluoroethylene (ETFE), polyvinylidene fluoride (PVDF), polychlorotrifluoroethylene (PCTFE), ethylene-chlorotrifluoroethylene (ECTFE) or fluorinated ethylene-propylene (FEP) copolymers.

As a variant, the substrate may be a lamination insert which ensures bonding with a rigid or flexible element. This polymeric lamination insert may especially be a layer based on polyvinyl butyral (PVB), ethylene-vinyl acetate (EVA), polyethylene (PE), polyvinyl chloride (PVC), thermoplastic urethane, polyurethane PU, ionomer, polyolefin-based adhesive, thermoplastic silicone or multi- or mono-component resin, which is thermally crosslinkable (epoxy, PU) or ultraviolet-crosslinkable (epoxy, acrylic resin).

The substrate may preferably be made of mineral glass, silicate glass, especially sodocalcic or silicosodocalcic glass, clear or extra clear glass, or a float glass. It may be a high-index glass (especially with an index of greater than 1.6).

The substrate may advantageously be a glass with an absorption coefficient of less than 2.5 m⁻¹ and preferably less than 0.7 m⁻¹ at the wavelength of OLED rays.

The choice is made, for example, from silicosodocalcic glasses with less than 0.05% of Fe(III) or Fe₂O₃, especially the Diamant glass from Saint-Gobain Glass, the Optiwhite glass from Pilkington, or the glass B270 from Schott. All the extra clear glass compositions described in document WO 04/025 334 may be chosen.

In an additional configuration, the substrate according to the invention comprises on a second main face a functional coat chosen from: a multilayer anti-reflection, an antifogging or antisoiling layer, an ultraviolet filter, especially a layer of titanium oxide, a luminophore layer, a mirror layer or a light extraction diffusing zone.

The OLED system may be suitable for emitting a (substantially) white light, which is as close as possible to the coordinates (0.33; 0.33) or coordinates (0.45; 0.41), especially at 0°.

To Produce substantially white light, several methods are possible: mixing of compounds (red, green, blue emission) in a single layer, stacking on the face of the electrodes three organic structures (red, green, blue emission) or two organic structures (yellow and blue).

The OLED device may be suitable for producing at the outlet a (substantially) white light, which is as close as possible to the coordinates (0.33; 0.33) or the coordinates (0.45; 0.41), especially at 0°.

The invention will now be described in greater detail with the aid of nonlimiting examples in which:

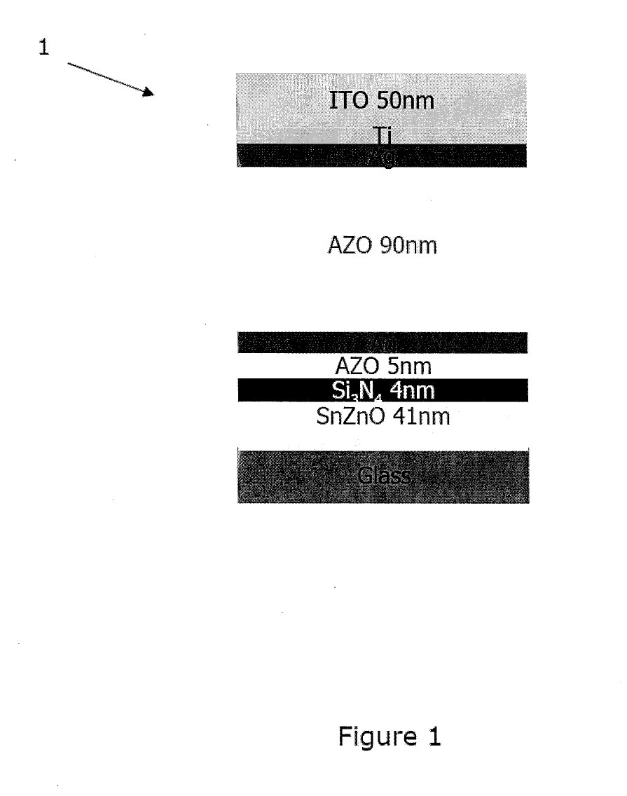

FIG. 1 represents a conductive support according to the invention.

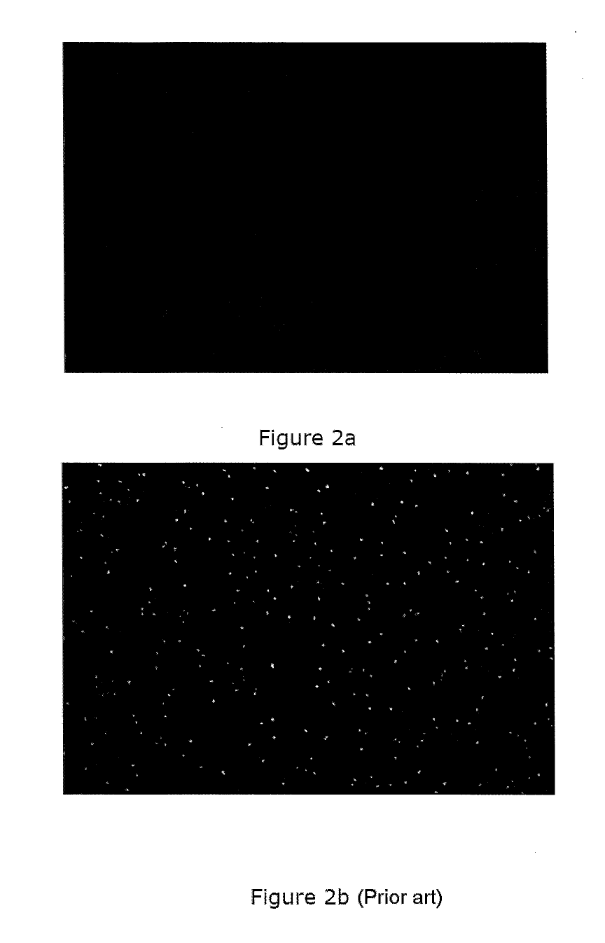

FIGS. 2a and 2b are optical microscopy images which are characteristic, respectively, of the conductive support of the prior art and of the conductive support according to the invention after annealing for one hour at 300° C.

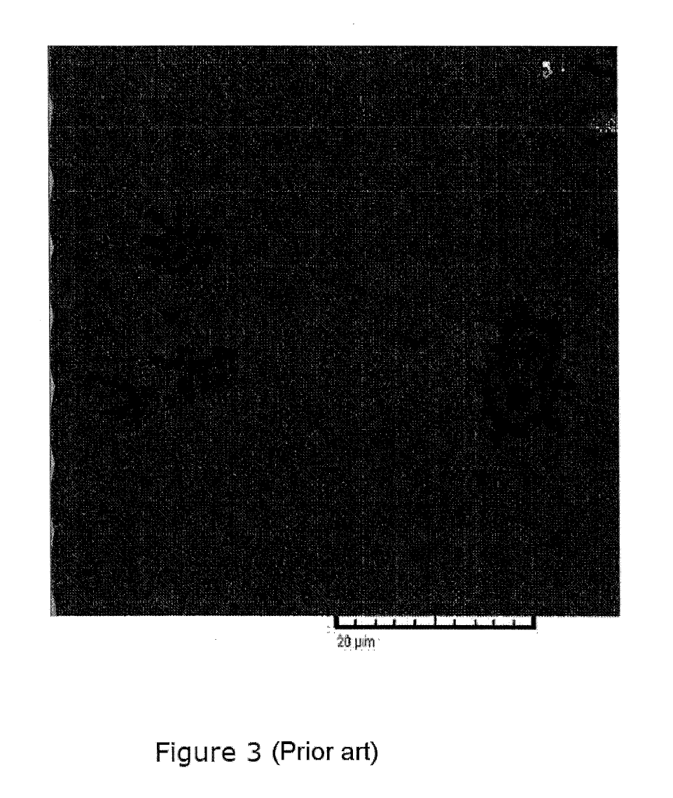

FIG. 3 is a scanning electron microscopy (SEM) image of observed dendrites of the conductive support of the prior art after annealing for one hour at 300° C.

### EXAMPLES

In a first deposition series, the preparation is performed by magnetron cathodic sputtering, firstly, on a mineral glass, of a stack of thin layers forming the transparent electrode according to the prior art, thus reproducing the stack of the abovementioned example 5 (example named Ex0), and, secondly, on a silicosodocalcic mineral glass of T_{L} of 92% with a thickness of 0.7 mm, of a stack of thin layers forming a transparent electrode according to the invention (example named Ex1) which differs from the electrode (Ex0) in that it comprises:
between the two silver layers the absence of the first overblocker, a single separating layer made of AZO whose thickness is increased to 90 nm, and
under the first silver layer a thin barrier layer of silicon nitride with a thickness of 4 nm, intercalated between SnZnO (which is preferably reduced to 41 nm) and AZO.

An example Ex1R is also presented, which is performed as a preliminary test by the Applicant and does not form part of the invention or of the prior art, differing from Ex1 by the presence of titanium.

Table 1 below shows in comparison the chemical composition and thickness of all of the layers forming these three electrodes.

TABLE 1

| Ex0 (comparative) | | Ex1 | | Ex1R | |
|---|---|---|---|---|---|
| ITO | 50 nm | ITO | 50 nm | ITO | 50 nm |
| Ti | <1 nm | Ti | <1 nm | Ti | <1 nm |
| Ag | 8 nm | Ag | 8 nm | Ag | 8 nm |
| AZO | 5 nm | | | | |
| SnZnO | 75 nm | | | | |
| AZO | 5 nm | AZO | 90 nm | AZO | 90 nm |
| Ti | <1 nm | | | Ti | <1 nm |
| Ag | 8 nm | Ag | 8 nm | Ag | 8 nm |
| AZO | 5 nm | AZO | 5 nm | AZO | 5 nm |
| — | — | SiAlN | 4 nm | SiAlN | 4 nm |
| SnZnO | 45 nm | SnZnO | 41 nm | SnZnO | 41 nm |

| | | |
|---|---|---|
| Glass | Glass | Glass |

FIG. 1 shows schematically the stack Ext.

More specifically, Si₃N₄ contains aluminum.

The conditions for the depositions by magnetron cathodic sputtering, of the layers for Ex0 have already been mentioned previously. The conditions for the depositions by magnetron cathodic sputtering for each of the layers of Ex1 and Ex1R are as follows:
the layer of SiAlN (Si₃N₄:Al) is deposited by reactive sputtering using a metal target of silicon doped with aluminum under an argon/nitrogen atmosphere,
each layer of SnZnO is deposited by reactive sputtering using a metallic target of zinc and tin under an argon/oxygen atmosphere,
each layer of AZO is deposited by sputtering using a ceramic target of zinc oxide and alumina under an argon/oxygen atmosphere, with a low oxygen content,
each silver layer is deposited using a silver target, under an atmosphere of pure argon,
the or each layer of Ti (overblocker) is deposited using a titanium target, under an atmosphere of pure argon,
the overlayer of ITO is deposited using a ceramic target of indium oxide and tin oxide under an argon atmosphere enriched with a small amount of oxygen, so as to make it sparingly absorbent, the ITO preferably becoming super-stoichiometric in oxygen.

The overblocker layer Ti may be partially oxidized after deposition of ITO thereon.

Table 2 below summarizes the deposition conditions and the refractive indices:

TABLE 2

| | | | | Refractive |
|---|---|---|---|---|
| | | Deposition | | index at |
| Layer | Target used | pressure | Gas | 550 nm |
| SiAlN | Si:Al at 92:8% by | 2 × 10⁻³ mbar | N₂/(Ar + N₂) | 2.04 |
| | weight | | at 43% | |
| AZO | Zn oxide = 98% | 2 × 10⁻³ mbar | O₂/(Ar + O₂) | 1.94 |
| | by weight | | at 1.6% | |
| | Al oxide = 2% by | | | |
| | weight | | | |
| SnZnO | Sn:Zn at 64:36% | 3.5 × 10⁻³ mbar | O₂/(Ar + O₂) | 2.06 |
| | by weight | | at 39% | |
| ITO | In oxide = 90% | 2 × 10⁻³ mbar | O₂/(Ar + O₂) | 2.03 |
| | by weight | | at 1% | |
| | Sn oxide = 10% | | | |
| | by weight | | | |
| Ti | Ti | 8 × 10⁻³ mbar | Ar at 100% | |
| Ag | Ag | 8 × 10⁻³ mbar | Ar at 100% | |

Alternatively, a metal target may be chosen of zinc and tin doped with antimony comprising, as total weight of the target, for example 65% Sn, 34% Zn and 1% Sb, or comprising, as total weight of the target, 50% Sn, 49% Zn and 1% Sb.

Given the refractive indices of the order of 2 for SnZnO, SiAlN, AZO, L1 is obtained equal to about 100 nm and L2 equal to about 180 nm to maximize the efficacy of the OLED, and even to conserve a small colorimetry angular dependency.

The electrodes Ex0, Ex1 and Ex1R are heated for 1 hour at a temperature of 300° C. (annealing). The following are measured before and after this annealing:
the light transmission (T_{L}),
the absorption (Abs),
the resistance per square (R□) of each of the electrodes, according to two measuring methods as explained hereinbelow.

The metal contact between the outer electrical circuit and the anode is taken at the surface of the anode, i.e. the ITO overlayer. The ITO overlayer is conductive and the charge carriers thus diffuse toward the second Ag layer, and are conducted laterally across the second Ag layer, to be injected thereafter into the organic layers, under the effect of the potential difference between the anode and the cathode, the latter being deposited over the last organic layer.

In order for the first Ag layer to be able to contribute toward the electrical conductivity of the anode, the current must be able to pass between the two Ag layers. The contribution of the first silver layer depends on the ratio between the vertical resistance, R_{Vert}, between the two Ag layers and the lateral resistance, R_{Lat}, between the center of the OLED and the edge of the OLED, where the carriers are injected into the anode from the external circuit.

R_{Vert} is proportional to the thickness and the resistivity of the layer structure between the two Ag layers, whereas R_{Lat} depends, inter alia, on the lateral distance, L_{Lat}.

If the vertical resistance R_{Vert}, between the two Ag layers is large relative to the lateral resistance R_{Lat}, the carriers will be transported mainly across the upper Ag layer, in contact with the conductive ITO overlayer.

The effective R□ of the anode then corresponds only to that generated by the second Ag layer. When this distance L increases, R_{Lat} increases, whereas R_{Vert} remains constant. From a certain lateral distance, the lateral resistance becomes comparable to the vertical resistance, and the carriers are transported across the two Ag layers. The effective R□ of the anode then corresponds to that generated by the two Ag layers.

The vertical resistance should therefore be as small as possible in order both to increase the size of the OLED for a given luminance uniformity and to reduce the energy consumption of the OLED, i.e. to increase its light efficiency (lm/W).

The R□ measured via the contactless method is of electromagnetic type, and is referred to here as R□_{Elm}, using the Nagy measuring equipment.

The R□ measured conventionally via the 4-point method is referred to herein as R□₄ₚ, using the Napson measuring equipment.

A substantially equal measured R□ via the 4-point and contactless techniques indicates that R_{Vert} and R_{Lat} are comparable. The distance involved in the 4-point measurement is 3 mm.

Table 3 below shows the results of these R□ measurements, before and after annealing, for the electrode Ex1, electrode Ex1R and comparative electrode Ex0, and also their optical properties.

TABLE 3

| | | Abs | R□₄ₚ | R□_{Elm} |
|---|---|---|---|---|
| EXAMPLES | T_{L} (%) | (%) | (Ω/□) | (Ω/□) |
| Ex0 before annealing | 85.0 | 7.0 | 5.8 | 2.8 |
| Ex0 after annealing | 81.0 | 11.0 | 9.0 | 4.9 |
| Ex1R before annealing | 82.3 | 9.3 | 2.9 | 2.8 |
| Ex1R after annealing | 86.4 | 7.4 | 2.4 | 2.3 |
| Ex1 before annealing | 82.6 | 9.5 | 2.9 | 2.8 |
| Ex1 after annealing | 86.5 | 7.4 | 2.5 | 2.4 |

Before annealing, the optical performance qualities of Ex0, Ex1 and Ex1R are comparable, unlike the electrical performance qualities. For Ex0, the R□₄ₚ measured via the 4-point technique (equal to 5.8Ω/□) corresponds to about twice the value given by the R□ₑₗₘ measurement (2.8Ω/□). The intermediate thick layer of SnZnO, before annealing, induces a high vertical resistance between the two Ag layers, such that, under the conditions of the 4-point measurement, the first Ag layer does not contribute toward the conductivity of the anode.

For Ex1 and Ex1R, the R□₄ₚ measured via the 4-point technique is substantially equal to the value given by the contactless measurement on account of the greater vertical conductivity of AZO relative to SnZnO, which shows that the vertical resistance of the separating layer is negligible, with regard to the manufacturing considerations of OLEDs, and of their size.

The invention also relates to an anode which is not intended to be annealed, especially at at least 250° C., for example when, alternatively, the substrate is made of plastic since the anode according to the invention proves to be better than the prior art even without annealing.

It is found that annealing results in degradation of the properties of the comparative prior art electrode Ex0, i.e.:
an increase in absorption,
a decrease in light transmission,
and an increase in the resistance per square,

whereas the electrode Ex1 according to the invention shows an improvement in these same properties (increase in T_{L} and decrease in Abs and in the resistance per square) especially by improving the crystallinity of the silver layers. The absorption is thus lowered from 9.5% to 7.4% after annealing.

After annealing, it is most particularly found that the R□ measured via the contact and contactless methods are equivalent for the electrode Ex1 (and Ex1R), which shows that the vertical resistance remains negligible, with regard to the manufacturing considerations of OLEDs, and of their size.

The surface state of Ex0 and Ex1 was then characterized by measuring the roughness parameters and by microscopic observation, and noteworthy surface properties for Ex1 were found, as detailed below.

The well-known roughness parameters, R_{q} and Rₘₐₓ, are measured by atomic force microscopy AFM on a 5×5 μm² measuring surface, and the measurements are collated in table 4 below.

TABLE 4

| | R_{q} | Rₘₐₓ |
|---|---|---|
| EXAMPLE | (nm) | (nm) |
| Ex0 before annealing | 0.5 | 5 |
| Ex0 after annealing | 0.6 | 6 |
| Ex1 before annealing | 0.6 | 6 |
| Ex1 after annealing | 0.7 | 7 |
| Ex1R before annealing | 1.5 | 10 |
| Ex1R after annealing | 1.7 | 12 |

The drawback of the anode Ex1R relative to the anode Ex1 is the degradation of the roughness R_{q}, which increases from 0.7 to 1.7 nm, and Rₘₐₓ which increases from 7 to 12 nm after annealing. This increase in roughness is explained by the crystalline nature of the AZO layer, whereas the amorphous SnZnO is less rough.

According to the invention, when the first overblocker is deleted, the roughness R_{q} is greatly decreased, from 1.7 to 0.7 nm. The reason for this improvement is not yet clarified. Possible reasons might be an etching effect on the surface of the silver layer by the plasma containing oxygen during the deposition of the additional AZO layer, and/or a modified growth mode of the additional AZO layer when it is deposited directly onto Ag.

The absence of the first overblocker induces, in counterpart, a degradation of the RE of 0.1-0.2Ω/□, but which remains minor, and thus acceptable with regard to OLED specifications.

FIGS. 2a and 2b are optical microscopy images characteristic, respectively, of the electrode Ex1 (according to the invention) and of the electrode Ex0 (according to the prior art) after annealing at 300° C. for 1 hour.

FIG. 3 is a scanning electron microscopy (SEM) image of dendrites observed for the comparative electrode Ex0.

On the image of FIG. 2a (Ex1), the absence of dendrites is observed, whereas, on the image of FIG. 2b (Ex0), numerous white points corresponding to the dendrites are observed, which are local depletions of silver which create, at the surface of the electrode, depressions with a depth of about 5 to 10 nm and a diameter ranging from about 10 nanometers up to about 10 micrometers, with a projecting part often being observed at the center of such a “well”, as shown in FIG. 3.

In Ex1, the use of the thin layer of Si₃N₄:Al as barrier layer between the first Ag layer and the first SnZnO layer makes it possible to prevent the formation of dendrites.

To manufacture an OLED, the organic layers (HTL/EBL (electron blocking layer)/EL/HBL (hole blocking layer)/ETL) are then deposited by vacuum evaporation so as to prepare an OLED which emits a white light. Finally, a metallic cathode made of silver and/or aluminum is deposited by vacuum evaporation directly onto the stack of organic layers.

Variants are possible while nevertheless remaining within the context of the invention, i.e. with a separating layer providing the lowest possible vertical resistance and low roughness.

An electrode Ex1′ was prepared by replacing in Ex1 the first sublayer of SnZnO with a TiO₂ layer. The TiO₂ layer is deposited by reactive sputtering using a ceramic target of titanium oxide under an argon atmosphere with addition of oxygen. The conditions are collated in table 5 below:

TABLE 5

| | | | | Refractive |
|---|---|---|---|---|
| | | Deposition | | index at |
| Layer | Target used | pressure | Gas | 550 nm |
| TiO₂ | Ti oxide | 2 × 10⁻³ mbar | O₂/(Ar + O₂) at 6% | 2.44 |

The electrode Ex1′ according to the invention shows, after annealing at 300° C. for 1 hour, an improvement in its properties (increase in T_{L} and decrease in absorption and in the resistance per square). Ex1′ conserves a sufficiently low vertical resistance before and particularly after annealing.

Moreover, it may be desired to use other sublayers such as the niobium oxide layer and to replace in Ex1 the first sublayer of SnZnO with a niobium oxide layer.

The SiO₂ layer is, itself, an alternative barrier layer. The layer of SiO₂ with aluminum is deposited by reactive sputtering using a metal target of silicon doped with aluminum, under an argon/oxygen atmosphere. The conditions are collated in table 6 below:

TABLE 6

| | | | | Refractive |
|---|---|---|---|---|
| | | Deposition | | index at |
| Layer | Target used | pressure | Gas | 550 nm |
| SiAlO | Si:Al at 92:8% by | 2 × 10⁻³ mbar | O₂/(Ar + O₂) | 1.47 |
| | weight | | at 74% | |

The barrier layer of silicon nitride doped with aluminum may alternatively be replaced with a silicon zirconium nitride layer SiZrN:Al prepared from a “metallic” target in total weight percentages of the following target: Si 76% by weight, Zr 17% by weight and Al 7% by weight, under a reactive atmosphere.

The AZO of the first contact layer and/or the second contact layer and/or the additional layer—and in particular the AZO of a separating monolayer—may be replaced (preferably for all these layers) with GZO prepared from a ceramic target, for example with 98% by weight of Zn oxide and 2% by weight of Ga oxide.

In a second deposition series, deposition is performed by magnetron cathodic sputtering on a silicosodocalcic mineral glass (such as the SGGF glass, with a thickness of mm), of two other stacks of thin layers of the transparent electrodes according to the invention (examples named Ex2 and Ex3) which differ from the electrode Ex1 by their sublayers. The first sublayer of SiAlN (Si₃N₄:Al) is deposited by reactive sputtering using a metal target made of silicon doped with aluminum, under an argon/nitrogen atmosphere as in example Ex1. The thin layer of SnZnO in Ex3 is deposited by reactive sputtering using a metal target of zinc and tin under an argon/oxygen atmosphere as in example Ex1.

Table 7 below shows the chemical composition and the thickness of all of the layers forming these two electrodes Ex2 and Ex3:

TABLE 7

| | |
|---|---|
| Ex2 | Ex3 |

| | | | |
|---|---|---|---|
| ITO | 50 nm | ITO | 50 nm |
| Ti | <1 nm | Ti | <1 nm |
| Ag | 8 nm | Ag | 8 nm |
| AZO | 90 nm | AZO | 90 nm |
| Ag | 8 nm | Ag | 8 nm |
| AZO | 5 nm | AZO | 5 nm |
| — | — | SnZnO | 5 nm |
| SiAlN | 45 nm | SiAlN | 40 nm |

| | |
|---|---|
| Glass substrate | Glass substrate |

The electrodes Ex2 and Ex3 are heated for 1 hour at a temperature of 300° C. (annealing). The following are measured after this annealing:
the light transmission (T_{L}),
the absorption (Abs),
the resistance per square (R□) of each of the electrodes, according to the two measuring methods.

Table 8 below shows the results of these measurements and of the R_{q}, after annealing, for the electrodes Ex2 and Ex3 according to the invention.

TABLE 8

| | | | R□₄ₚ | R□_{Elm} | R_{q} |
|---|---|---|---|---|---|
| EXAMPLES | T_{L} (%) | Abs (%) | (Ω/□) | (Ω/□) | (nm) |
| Ex2 after annealing | 86.6 | 7.3 | 2.6 | 2.5 | 0.7 |
| Ex3 after annealing | 86.6 | 7.1 | 2.4 | 2.3 | 0.6 |

The electrodes Ex2 and Ex3 according to the invention show an improvement in their properties after annealing (increase in T_{L} and decrease in the absorption and in the resistance per square).

Just as for Ex1, after annealing, by virtue of the separating layer, it is most particularly found that the R□ values measured via the 4-point and contactless methods are equivalent for each of the electrodes Ex2 and Ex3, which shows that the vertical resistance of the separating layer is negligible, with regard to the manufacturing considerations of OLEDs, and of their size.

Moreover, the roughness remains remarkably low.

The large thickness of the AZO layer used for the separating monolayer in the preceding examples according to the invention may make each stack too fragile with regard to certain chemical procedures, especially those involving acidic treatments, or long exposure times to high humidity levels.

Thus, even when thin, the intermediate layer preferably made of SnZnO may remain essential for the better resistance to chemical treatments of the OLED, namely cleaning, especially according to the following procedure:
washing with a detergent at a pH between 6 and 7 at 50° C. under ultrasonication (at 35 kHz) for 10 minutes,
rinsing with H₂O at 50° C. without ultrasonication for 10 minutes,
rinsing with H₂O at 50° C. under ultrasonication (at 130 kHz) for 10 minutes. The detergent is TFDO W sold by Franklab SA. It is organic, non-foaming, with ionic and nonionic surfactants, chelating agents and stabilizers. The pH is about 6.8 at 3% dilution.

By observation of the surface when it is thus treated, on an optical microscope at a magnification of ×10, a few pits or surface defects of the order of about 10 μm may be observed in the abovementioned examples Ex1, Ex2 and Ex3.

New examples were prepared by inserting into the separating layer a thin intermediate layer preferably chosen from SnZnO. This thus gives an additional layer of AZO, the intermediate layer of SnZnO with a thickness of less than 15 nm, a second contact layer of AZO with a thickness of less than 10 nm here. However, it may suffice to replace in the separating layer of Ex1 the AZO monolayer with a GZO monolayer which is chemically more inert.

Table 9 below shows the chemical composition and the thickness of all of the layers forming these two electrodes Ex2bis and Ex3bis.

TABLE 9

| | |
|---|---|
| Ex2bis | Ex3bis |

| | | | |
|---|---|---|---|
| ITO | 50 nm | ITO | 50 nm |
| Ti | <1 nm | Ti | <1 nm |
| Ag | 8 nm | Ag | 8 nm |
| AZO | 5 nm | AZO | 5 nm |
| SnZnO | 5 nm | SnZnO | 5 nm |
| AZO | 95 nm | AZO | 95 nm |
| Ag | 8 nm | Ag | 8 nm |
| AZO | 5 nm | AZO | 5 nm |
| — | — | SnZnO | 5 nm |
| SiAlN | 45 nm | SiAlN | 40 nm |

| | |
|---|---|
| Glass substrate | Glass substrate |

The electrodes Ex2bis and Ex3bis are heated for 1 hour at a temperature of 300° C. (annealing). The following are measured after this annealing:
the light transmission (T_{L}),
the absorption (Abs),
the resistance per square (R□) of each of the electrodes, according to the two measuring methods.

Table 10 below shows the results of these measurements and of the R_{q}, after annealing, for the electrodes Ex2bis and Ex3bis according to the invention.

TABLE 10

| | | Abs | R□₄ₚ | R□_{Elm} | R_{q} |
|---|---|---|---|---|---|
| EXAMPLES | TL (%) | (%) | (Ω/□) | (Ω/□) | (nm) |
| Ex2bis after annealing | 86.8 | 7.2 | 2.6 | 2.5 | 0.7 |
| Ex3bis after annealing | 86.9 | 7.1 | 2.5 | 2.4 | 0.6 |

The electrodes Ex2bis and Ex3bis according to the invention show an improvement in their properties after annealing (increase in T_{L} and decrease in absorption and in resistance per square).

Just as for Ex1, after annealing, by virtue of the separating layer, it is most particularly found that after annealing, the R□ values measured via the contact and contactless methods are equivalent for each of the electrodes Ex2bis and Ex3bis, which shows that the vertical resistance remains negligible even with the thin intermediate layer, with regard to the manufacturing considerations of OLEDs, and of their size.

Moreover, the roughness remains remarkably low.

Moreover, by observation of the surface when it is treated according to the treatment already indicated, no pitting or surface defects are visible on an optical microscope at a magnification of ×10.

Moreover, as illustrated in Ex2bis and Ex3bis, it is preferred for the upper face (the face that is the more remote from the substrate) of the thin intermediate layer to be closer to the second silver layer than the lower face (the face that is closer to the substrate) of the first silver layer.

As an acceptable alternative in the examples already described of the invention, the contact layers AZO are replaced with ZnSnO with less than 5% by weight of Sn (as total weight of metal).

Even if it is preferred to insert in an advantageous embodiment only one intermediate layer SnZnO, another embodiment consists in inserting one or more other layers of SnZnO into the additional layer of AZO, and thus N other identical layers of SnZnO (preferably N<4), each layer i of SnZnO having a thickness tᵢ and being located a distance dᵢ from the second Ag layer and, for example, regularly distributed and/or of the same thickness (less than or equal to 8 nm, for example 5 nm in particular).

In other words, the additional layer with a thickness e₂ is formed by two disjointed AZO “buffer” layers, each with a thickness e₂₁ and e₂₂ of 42 nm (with e₂₁ and e₂₂ equal to e₂ and equal to 84 nm here).

This type of stack is capable of further improving the surface roughness, and/or the chemical durability. An example Ex4 is presented in table 11 below with N=2:

TABLE 11
Ex4

| | |
|---|---|
| ITO | 50 nm |
| Ti | <1 nm |
| Ag | 8 nm |
| AZO | 5 nm |
| SnZnO | 5 nm |
| 2^{nd} AZO buffer layer | 42 nm |
| SnZnO | 5 nm |
| 1^{st} AZO buffer layer | 42 nm |
| Ag | 8 nm |
| AZO | 5 nm |
| SnZnO | 5 nm |
| SiAlN | 45 nm |

Glass substrate

Similarly, after annealing, the R□ values measured via the 4-point and contactless methods are substantially equal, and the optical and electrical properties are greatly improved.

Replacement of the thick layers of SnZnO between the Ag layers with AZO layers was also tested for stacks containing three Ag layers, and thus the separating layer was repeated between the middle silver layer and the last silver layer. The AZO layers are thus directly on the first silver layer and on the middle silver layer. In a similar manner to the bi-Ag stacks, the dendrites are deleted after annealing, the R□ values measured via the 4-point and contactless methods are substantially equal, of very low roughness, and the optical and electrical properties are greatly improved after annealing.

The electrodes presented as examples thus satisfy the following specifications:
they have the lowest possible roughness, preferably with R_{q} less than or equal to 1 nm and Rₘₐₓ less than or equal to 15 nm,
they have a sufficiently low vertical resistance between the first and the second layer of silver,

and preferably:
they conserve an acceptable resistance per square or even lower the resistance per square after annealing,
they conserve acceptable absorption or even lower the absorption after annealing,
they conserve acceptable light transmission or even increase it after annealing.

1. A conductive support for an organic light-emitting diode (OLED) device, comprising a transparent glass substrate bearing, on a first main face, a transparent electrode, which comprises the following stack of thin layers in this order:
a dielectric sublayer with a first optical thickness of greater than 20 nm and less than 180 nm, comprising
a first crystalline contact layer based on zinc oxide, and
a first metal layer, based on silver, with a thickness of less than 20 nm,
a dielectric separating layer, with a second optical thickness of greater than 80 nm and less than 280 nm, comprising, in this order
an additional crystalline layer based on zinc oxide with a thickness e₂, directly on the first metal layer based on silver,
an optional amorphous intermediate layer based on tin zinc oxide or based on indium zinc oxide or based on indium zinc tin oxide, with a thickness eᵢ of less than 15 nm,
a second crystalline contact layer based on zinc oxide, with a thickness e_{c2}, the sum of the thicknesses e_{c2}+e₂ being at least 30 nm,
a second metal layer, based on silver, with a thickness of less than 20 nm,
an overblocker layer, directly on the second metal layer based on silver, which comprises a metal layer based on at least one of the following metals: Ti, V, Mn, Fe, Co, Cu, Zn, Zr, Hf, Al, Nb, Ni, Cr, Mo, Ta, W, with a thickness of less than 3 nm, and
an electrically conductive overlayer directly on the overblocker layer.

2. The conductive support (1) as claimed in claim 1, wherein at least 60% of the thickness of the dielectric separating layer is formed from the thickness e₂ and/or e₂ is greater than or equal to 35 nm and the amorphous intermediate layer is present.

3. The conductive support as claimed in claim 1, wherein the additional crystalline layer consists essentially of zinc oxide doped with aluminum and/or gallium and wherein the second crystalline contact layer consists essentially of zinc oxide doped with aluminum and/or gallium with a thickness e_{c2} of less than or equal to 10 nm.

4. The conductive support as claimed in claim 1, wherein the dielectric sublayer comprises, under the first crystalline contact layer, first sublayer, chosen from at least one of the following layers:
a layer based on tin zinc oxide,
a layer based on titanium oxide, optionally containing zirconium,
a layer based on niobium oxide.

5. The conductive support as claimed in claim 1, wherein the dielectric sublayer comprises, under the first crystalline contact layer, a first sublayer of oxide, which is preferably amorphous, and the first sublayer is subjacent to a barrier layer, which is in contact with the first sublayer and is directly under the first crystalline contact layer, the barrier layer being based on silicon nitride and optionally on zirconium or based on silica or alternatively based on aluminum nitride, the barrier layer having a thickness of less than 15 nm.

6. The conductive support as claimed in claim 1, wherein a layer based on silicon nitride and optionally on zirconium is the first thin layer of the dielectric sublayer, optionally directly on the transparent substrate, and has a thickness of greater than 20 nm.

7. The conductive support as claimed in claim 1, wherein the dielectric separating layer successively comprises, in sequence, the additional crystalline layer consisting essentially of zinc oxide, the optional amorphous intermediate layer consisting essentially of tin zinc oxide which is optionally doped, with a thickness eᵢ of less than or equal to 8 nm, the second crystalline contact layer which consists essentially of zinc oxide which is doped, and the sum e_{c2}+e₂ being at least 50 nm, and a roughness R_{q} of the transparent electrode is less than 1.5 nm.

8. The conductive support as claimed in claim 1, comprising said optional amorphous intermediate layer, wherein one or more other amorphous layers each of thickness e_{Li} less than 15 nm divide the additional crystalline layer into several buffer layers, each other amorphous layer being based on the same oxide as that of the optional amorphous intermediate layer.

9. The conductive support as claimed in claim 1, wherein the dielectric separating layer is a crystalline monolayer and consists essentially of zinc oxide, e₂ being at least 50 nm, and a roughness R_{q} of the transparent electrode is less than 1.5 nm.

10. The conductive support as claimed in claim 1, wherein the electrically conductive overlayer comprises, as the last layer, a layer based on at least one of the following metal oxides, optionally doped: indium tin oxide, indium zinc oxide, molybdenum oxide, tungsten oxide, vanadium oxide.

11. The conductive support as claimed in claim 1, wherein the overblocker layer, which comprises a metal layer, is based on at least one of the following metals: Ti, Nb, Ni, Cr, Ta, and/or based on an alloy with at least two of said metals.

12. The conductive support as claimed in claim 1, wherein the stack comprises, one of the following stacks:
first amorphous sublayer SnZnO/barrier layer/first contact layer AZO or (A)GZO/Ag/additional crystalline layer AZO or (A)GZO (/amorphous intermediate layer SnZnO/) second contact layer AZO or (A)GZO/Ag/overblocker/overlayer, or
or first amorphous sublayer of titanium oxide/barrier layer/first contact layer AZO or (A)GZO/Ag/additional crystalline layer AZO or (A)GZO (/amorphous intermediate layer SnZnO)/second contact layer AZO or (A)GZO/Ag/overblocker/overlayer, or
or first sublayer of niobium oxide (/barrier layer)/first contact layer AZO or (A)GZO/Ag/additional crystalline layer AZO or (A)GZO (/amorphous intermediate layer SnZnO)/second contact layer AZO or (A)GZO/Ag/overblocker/overlayer, or
or first sublayer Si(Zr)N/(amorphous layer SnZnO less than 10 nm)/first contact layer AZO or (A)GZO/Ag/additional crystalline layer AZO or (A)GZO/amorphous intermediate layer SnZnO/second contact layer AZO or (A)GZO/Ag/overblocker/overlayer, preferably ITO,
and wherein a roughness R_{q} of the transparent electrode is less than 1 nm.

13. The conductive support as claimed in claim 1, wherein the stack comprises one of the following stacks:
first amorphous sublayer SnZnO or of titanium oxide/barrier layer/first contact layer AZO or GZO/Ag/crystalline separating layer AZO or GZO/Ag/titanium overblocker/overlayer,
first sublayer Si(Zr)N/(amorphous layer SnZnO less than 10 nm)/Ag/crystalline separating layer AZO or GZO/Ag/titanium overblocker/overlayer.

14. The conductive support as claimed in claim 1, wherein the stack has a difference in absolute value of R□₄ₚ-R□ₑₗₘ of less than 0.7×R□ₑₗₘ, with R□ₑₗₘ being the resistance per square measured via an electromagnetic contactless method and R□₄ₚ being the resistance per square measured via the 4-point method.

15. A process for manufacturing a conductive support for an organic light-emitting diode (OLED) device, comprising a transparent glass substrate bearing, on a first main face, a transparent electrode, the process comprising:
depositing over the first main face a dielectric sublayer with a first optical thickness of greater than 20 nm and less than 180 nm, comprising
a first crystalline contact layer based on zinc oxide, and
a first metal layer, based on silver, with a thickness of less than 20 nm,
depositing a dielectric separating layer, with a second optical thickness of greater than 80 nm and less than 280 nm, comprising, in this order
an additional crystalline layer based on zinc oxide, with a thickness e₂, directly on the first metal layer based on silver,
an optional amorphous intermediate layer based on tin zinc oxide or based on indium zinc oxide or based on indium zinc tin oxide, with a thickness eᵢ of less than 15 nm,
a second crystalline contact layer based on zinc oxide, with a thickness e_{c2}, the sum of the thicknesses e_{c2}+e₂ being at least 30 nm,
depositing a second metal layer, based on silver, with a thickness of less than 20 nm, depositing an overblocker layer, directly on the second metal layer based on silver, which comprises a metal layer based on at least one of the following metals: Ti, V, Mn, Fe, Co, Cu, Zn, Zr, Hf, Al, Nb, Ni, Cr, Mo, Ta, W, with a thickness of less than 3 nm, and depositing an electrically conductive overlayer directly on the overblocker layer, wherein the additional layer deposited on the first silver metal layer based on silver is made of zinc oxide and is prepared by cathodic sputtering using a ceramic target of zinc oxide, with, during the deposition, an oxygen content of greater than or equal to 0% and less than 10% and a content of noble gas(es) of at least 90%,
wherein when the second crystalline contact layer is above the optional amorphous intermediate layer, the second crystalline contact layer is made of zinc oxide and is prepared by cathodic sputtering using a ceramic target of zinc oxide, with, during the deposition, an oxygen content of greater than or equal to 0% and less than 10% and a content of noble gas(es) of at least 90%,
wherein the first contact layer is prepared by cathodic sputtering using a ceramic target of zinc oxide, with, during the deposition, an oxygen content of greater than or equal to 0% and less than 10% and a content of noble gas(es) of at least 90%.

16. An organic light-emitting diode (OLED) device comprising the conductive support as claimed in claim 1.

17. A process for manufacturing the OLED device as claimed in claim 15, further comprising, before depositing a organic light-emitting system, heating the transparent electrode to a temperature above 180° C., for a time of between 5 minutes and 120 minutes.
